(19) United States
(12) Patent Application Publication
(10) Pub. No.: US 2011/0209747 A1
(43) Pub. Date: Sep. 1, 2011

(54) POLYESTER FILM, MANUFACTURING METHOD THEREOF, POLYESTER FILM FOR SEALING BACK FACE OF SOLAR CELL, PROTECTIVE FILM FOR BACK FACE OF SOLAR CELL, AND SOLAR CELL MODULE

(75) Inventor: Zemin SHI, Kanagawa (JP)

(73) Assignee: FUJIFILM CORPORATION, Tokyo (JP)

(21) Appl. No.: 13/035,385

(22) Filed: Feb. 25, 2011

(30) Foreign Application Priority Data
Feb. 26, 2010 (JP) 2010-043452

(51) Int. Cl. H01L 31/048; B32B 27/36; B29C 47/88

(52) U.S. Cl. 136/251; 428/220; 264/177.17

(57) ABSTRACT

A biaxially oriented polyester film having: an equilibrium moisture content of from 0.1% by mass to 0.25% by mass; a difference between moisture contents measured at 10 cm intervals of from 0.01% by mass to 0.06% by mass; a degree of crystallinity of from 30% to 40%; a concentration of terminal carboxyl groups of from 5 equivalents/ton to 25 equivalents/ton; and a thickness of from 100 μm to 350 μm.

### CROSS-REFERENCE TO RELATED APPLICATION

This application claims priority under 35 USC 119 from Japanese Patent Application No. 2010-043452 filed on Feb. 26, 2010, the disclosure of which is incorporated by reference herein.

### BACKGROUND OF THE INVENTION

1. Field of the Invention

The present invention relates to a polyester film, a manufacturing method thereof, a polyester film for sealing the back face of a solar cell, a protective film for the back face of a solar cell, and a solar cell module.

2. Description of the Related Art

In recent years, from the viewpoints of global environmental protection, much attention has been given to photovoltaic generation that converts sunlight into electricity. A solar cell module which is used for photovoltaic generation has a structure in which (a sealing material)/a solar cell device/a sealing material/a back sheet are laminated in this order on a glass substrate onto which sunlight is incident.

A solar cell module is required to have a high degree of weather resistance so that the solar cell module can retain cell performance, such as power generation efficiency, over a long period of several decades even under an extreme usage environment of strong wind and rain or direct sunlight. To provide such weather resistance, materials, such as a back sheet and a sealing material that seals a device in a solar cell module, are also required to have weather resistance. In addition, adhesion between such materials, for example, between a back sheet and a sealing material (for example, ethylene vinyl acetate copolymer (EVA)) is required to have a high degree of weather resistance.

Generally, a resin material, such as polyester, is used in a back sheet in a solar cell module. Normally, a lot of carboxyl groups or hydroxyl groups are present on the surface of polyester, therefore it is highly likely that hydrolysis will occur in a humid environment, and thus the material tends to degrade over time. Therefore, polyester used for a solar cell module which is placed in an environment such as one exposed to wind and rain at all times, for example, outdoors, is required to suppress the hydrolysis property. However, for example, if an attempt is made to reduce the acid value to suppress the hydrolysis property, the control is difficult, the amount of carboxyl groups or hydroxyl groups on the film surface is excessively reduced, and the adhesion becomes insufficient.

As a technology related to the above and as a method to improve adhesion in the case of using polyester, for example, a technology has been disclosed that suppresses delamination (interlayer peeling) by controlling the X-ray diffraction intensity ratio (plane orientation) of polyester in a specific range to suppress poor adhesion (peeling) induced by cohesive failure inside a PET film (for example, refer to Japanese Patent Application Laid-Open (JP-A) No. 2007-268710).

In addition, a film for sealing the back face of a solar cell has been disclosed in which a thermal adhesion layer is laminated on a polyester film (for example, refer to JP-A No. 2003-60218).

Also, a polyester film for sealing the back face of a solar cell has been disclosed that has a content of a catalyst-derived titanium compound and a phosphorus compound in a specific range and a concentration of terminal carboxyl groups of 40 equivalents/ton (eq/t) or less (for example, refer to JP-A No. 2007-204538).

However, in the polyester film showing a specific X-ray diffraction intensity ratio (plane orientation), hydrolysis of the PET cannot be suppressed over a long period of time, and thus the molecular weight decreases, so that the surface becomes embrittled and adhesive failure occurs. In addition, in the film in which a thermal adhesion layer is laminated, likewise, the surface becomes embrittled over time and the thermal adhesion layer becomes decomposed over time, so that the adhesion force becomes weaker.

As described in the above, in the conventional art, when weather resistance is tested over a long time, hydrolysis resistance and dimension stability over time are not yet sufficient due to the progress of hydrolysis, and therefore the hydrolysis resistance and the dimension stability have not yet both been satisfied at the same time. Particularly, when manufacturing thick films, it is desired to make further improvement in the hydrolysis resistance and the dimension stability in terms of the long term weather resistance.

### SUMMARY OF THE INVENTION

According to an aspect of the invention, there is provided a biaxially oriented polyester film having:

an equilibrium moisture content of from 0.1% by mass to 0.25% by mass;

a difference between moisture contents measured at 10 cm intervals of from 0.01% by mass to 0.06% by mass;

a degree of crystallinity of from 30% to 40%;

a concentration of terminal carboxyl groups of from 5 equivalents/ton to 25 equivalents/ton; and a thickness of from 100 μm to 350 μm.

### BRIEF DESCRIPTION OF THE DRAWINGS

FIG. 1 is a view showing the relationship between the stretch ratio and the degree of plane orientation of a PET film.

FIG. 2 is a view showing the relationship between the degree of plane orientation and the equilibrium moisture content of a PET film.

FIG. 3 is a view showing the relationship between the equilibrium moisture content and the increase of terminal COOH groups after a thermal treatment of a PET film.

FIG. 4 is a view showing the relationship between the heat setting temperature and the retention rate of the elongation at rupture after a thermal treatment of a PET film.

FIG. 5 is a cross-sectional view schematically showing a configuration example of a solar cell module.

### DETAILED DESCRIPTION OF THE INVENTION

Hereinafter, the present invention will be described in detail.

Generally, a polyester film tends to show a worse hydrolysis resistance as the thickness of the polyester film increases so that the polyester film cannot be used over a long period of time.

However, as a result of consistent study, the inventor of the present invention has found that it is possible to obtain a polyester film that exhibits an improved degree of orientation and thus a decreased moisture content and is excellent in terms of hydrolysis resistance and shape stability, even if it is a thick film, by rapidly cooling a thick molten film-shaped polyester ejected from an extrusion die and stretching it with a predetermined stretching stress.

Firstly, the tests performed by the inventor of the present invention will be described.

The degree of plane orientation An showing the degree of molecular order is represented by the formula below in which nTD represents the index of refraction in the film width direction, and nMD represents the index of refraction in the film manufacturing direction (length direction).

Δn=[(nTD+nMD)/2−nND]

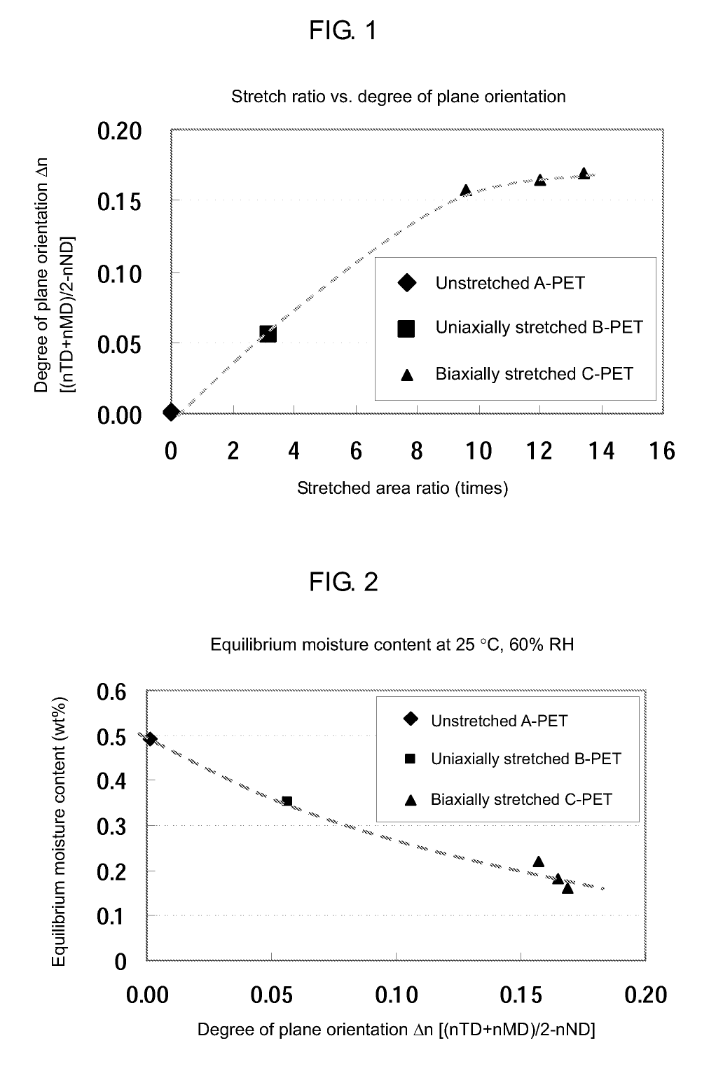

As shown in FIG. 1, compared with the degree of plane orientation of an unstretched PET film, a uniaxially longitudinally stretched PET film has an increased degree of plane orientation, and particularly, a biaxially stretched PET film has a greatly increased degree of plane orientation.

As a result of studying the relationship between the degree of plane orientation of each PET film and the equilibrium moisture content (25° C., 60% RH), it has been found that, as shown in FIG. 2, it is possible to suppress the equilibrium moisture content to a lower level as the degree of plane orientation increases.

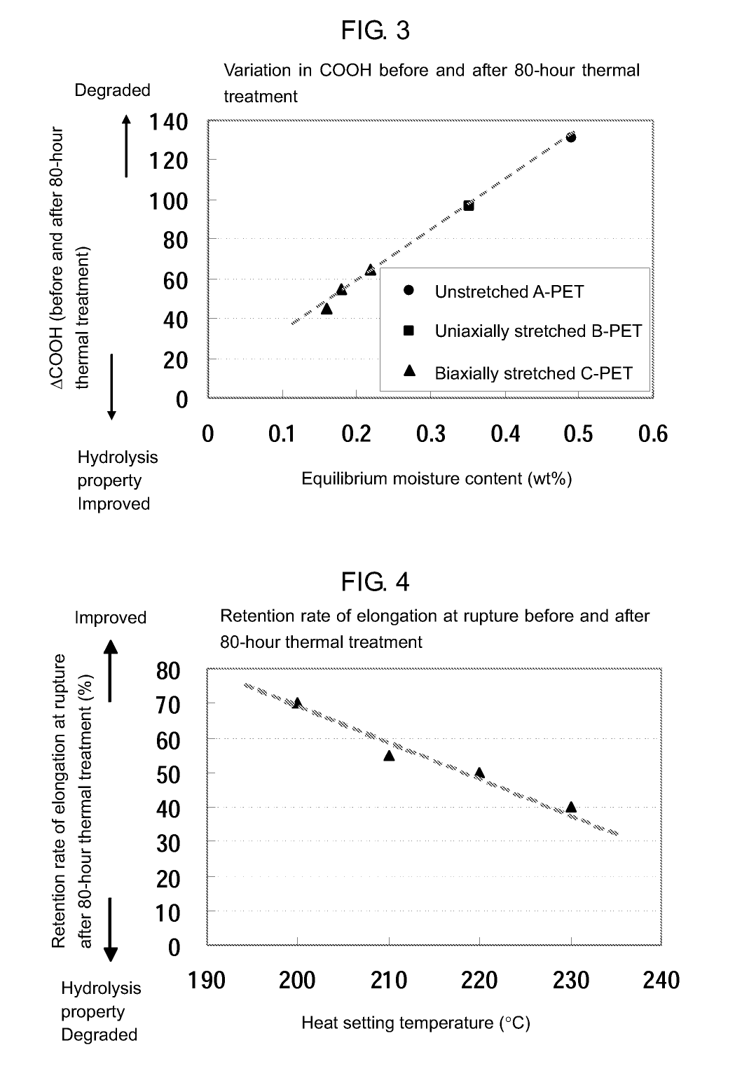

Furthermore, as a result of measuring the variation in terminal carboxyl groups before and after a thermal treatment which simulate an extreme environment (120° C., 100% RH, 80 hr), it has been found that, as shown in FIG. 3, the increase in terminal carboxyl groups is reduced and the hydrolysis resistance becomes further improved as the equilibrium moisture content decreases.

In addition, as a result of measuring the temperature at which the biaxially stretched PET film is thermally set and the retention rate of the elongation at rupture before and after the thermal treatment (120° C., 100% RH, 80 hr), the inventor of the present invention has found that, as shown in FIG. 4, the retention rate of the elongation at rupture becomes larger and the hydrolysis resistance becomes further improved as the heat setting temperature lowers.

The present invention has been completed based on these findings.

<Polyester Film>

The polyester film according to the present invention is a biaxially oriented polyester film having:

an equilibrium moisture content of from 0.1% by mass to 0.25% by mass;

a difference between moisture contents measured at 10 cm intervals of from 0.01% by mass to 0.06% by mass;

a degree of crystallinity of from 30% to 40%;

a concentration of terminal carboxyl groups of from 5 equivalents/ton to 25 equivalents/ton; and

a thickness of from 100 μm to 350 μm.

Hereinafter, the properties of the polyester film according to the present invention will be described in detail.

—Equilibrium Moisture Content and Difference Between Moisture Contents—

The polyester film according to the present invention has an equilibrium moisture content of from 0.1% by mass to 0.25% by mass and a difference between moisture contents measured at 10cm intervals of from 0.01% by mass to 0.06% by mass.

The equilibrium moisture content and the difference between moisture contents of the film are obtained as follows.

In the film, a total of 20 samples are taken arbitrarily at ten points along the length direction of the film at 10 cm intervals and at ten points along the width direction at 10 cm intervals, and the moisture content of each sample is measured as follows.

The polyester film is placed in a condition of 25° C. and 60% RH for three days for moisture control, and then the moisture content of the film is measured at 200° C. using a trace moisture analyzer (Karl Fischer method). The average value of the moisture contents of the 20 samples is defined as the equilibrium moisture content of the film.

In addition, the difference between the largest value and the smallest value in the moisture content values of the 20 samples is defined as the difference between moisture contents of the film.

If the equilibrium moisture content of the polyester film exceeds 0.25% by mass, hydrolysis easily occurs in an extreme outdoor environment where a solar cell is placed, but the equilibrium moisture content of the polyester film according to the present invention is 0.25% by mass or less, and therefore hydrolysis is effectively suppressed even in an extreme environment, so that the rupture strength is retained for a long time. However, if the equilibrium moisture content is less than 0.1% by mass, the handling property deteriorates, and dimension change due to moisture absorption occurs easily, and therefore the film is unsuitable to be manufactured as a protective film for the back face of a solar cell.

From the viewpoints of further improving hydrolysis resistance, the equilibrium moisture content of the polyester film according to the present invention is preferably from 0.12% by mass to 0.23% by mass, and more preferably from 0.13% by mass to 0.20% by mass.

If the difference between moisture contents exceeds 0.06% by mass, dimension stability deteriorates, deformation easily happens when used outdoors, and the film is easily peeled off in the case of using the film as a protective film for the back face of a solar cell. However, if the difference between moisture contents is less than 0.01% by mass, manufacturing complexity rises, and precise control of the process conditions becomes difficult.

From the viewpoints of further improving dimension stability, the difference between moisture contents of the polyester film according to the present invention is preferably from 0.01% by mass to 0.05% by mass, and more preferably from 0.02% by mass to 0.04% by mass.

—Degree of Crystallinity—

The polyester film according to the present invention has a degree of crystallinity of from 30% to 40%.

The degree of crystallinity of the film can be obtained by the formula below wherein dA represents the density of completely amorphous polyester; dC represents the density of completely crystalline polyester; and d represents the density of a sample.

Degree of crystallinity (%)={(d−dA)/(dC−dA)}×100

In the case of polyethylene terephthalate (PET), in the above formula, the density of a completely amorphous PET (dA) and the density of a completely crystalline PET (dC) are 1.335 and 1.501, respectively.

If the degree of crystallinity of the polyester film is less than 30%, the amount of oriented crystals generated is insufficient, the dimension stability of the film deteriorates, and the mechanical strength becomes insufficient, and if the degree of crystallinity of the polyester film exceeds 40%, the oriented crystal component becomes excessive and the film becomes embrittled, and therefore the hydrolysis resistance of the film deteriorates in a long term durability test.

Meanwhile, from the viewpoints of satisfying both the dimension stability and the hydrolysis resistance, the degree of crystallinity of the polyester film according to the present invention is preferably from 32% to 39%, and further preferably from 33% to 38%.

—Concentration of Terminal Carboxyl Groups—

The polyester film according to the present invention has a concentration of terminal carboxyl groups (terminal COOH) of from 5 equivalents/ton to 25 equivalents/ton.

If the concentration of terminal carboxyl groups (terminal COOH) is less than 5 equivalents/ton, interlayer adhesion deteriorates when the films are laminated, and if the concentration of terminal carboxyl groups (terminal COOH) exceeds 25 equivalents/ton, hydrolysis easily occurs, and therefore an increase in the concentration of terminal COOH before and after weather resistance test, which is one of the indices of hydrolysis resistance, becomes larger.

While hydrolysis resistance can be improved by reducing terminal COOH, if an attempt is made to reduce terminal COOH, the amount of carboxylic acid groups on the surface of the film (hereinafter, referred to as ‘surface COOH amount’) also decreases, and therefore adhesion strength deteriorates when the film is adhered to an object.

In the present invention, even in the case of having a relatively thick film thickness in a range of from 100 μm to 350 μm, since terminal carboxylic acid groups are not completely removed but retained in a small amount in the polyester that composes the film, and terminal carboxyl groups are present in a predetermined range, hydrolysis property can be suppressed at a low level, and adhesion with an object can be increased. Thereby, since degradation can be suppressed over a long period of time, for example, in the case of constituting a solar cell module, the adhesion with, for example, a sealing agent is maintained over a long period of time, dimension stability can be maintained over a long period of time, and a desired power generation performance can be stably obtained over a long period of time.

—Thickness—

The thickness (after being completely stretched) of the polyester film according to the present invention is from 100 μm to 350 μm, and preferably from 255 μm to 350 μm, and further preferably from 260 μm to 340 μm.

If the thickness of the polyester film is 100 μm or more, the film has a high rupture strength and is preferable as a protective film for the back face of a solar cell. However, if the thickness exceeds 350 μm, it becomes difficult to achieve the equilibrium moisture content and the degree of crystallinity in the above ranges when manufacturing the film.

In the polyester film according to the present invention, from the viewpoints of suppressing the moisture content at a low level by controlling the degree of crystallinity in the above range when the film is stretched, and further improving the rupture strength by making the film thick, the thickness is preferably from 255 μm to 350 μm, and further preferably from 260 μm to 340 μm.

When the thickness of the film after stretching is in the above range, since the thickness of melt film (a molten film-shaped resin) extruded from a die can be made thick, the equilibrium moisture content can be suppressed to a low level by increasing the stretch ratio and thus increasing the degree of plane orientation (refer to FIGS. 1 and 2), and a thick biaxially oriented polyester film can be obtained.

That is, in the present invention, it is possible to increase hydrolysis resistance in a case in which the film has a relatively thick thickness such as above.

If such a thick film is made, there are advantages of improving weather resistance (particularly hydrolysis resistance) and dimension stability when manufacturing a thick film, which cannot be achieved by the conventional art.

In a thin range in which the thickness of the polyester film is less than 100 μm, the ratio of the surface with respect to the entire film increases, and therefore weather resistance easily deteriorates. That is, since hydrolysis proceeds from the surface, in the beginning, the molecular weight on the surface decreases and then the film is embrittled. If the thickness of the film is thin, the film is affected by such embrittlement and thus easily ruptured, and the ratio of the elongation at rupture (before/after) and the ratio of the rupture strength (before/after) before and after a long time span (thermal condition) become larger, and the weather resistance becomes worse as the ratios become larger. Conversely, if the thickness of the polyester film exceeds 500 μm, the bending elasticity becomes too large, and therefore cracks occur on a pass roll through which the film passes while manufacturing the film. Therefore, hydrolysis easily proceeds therefrom, and the elongation at rupture after the thermal treatment deteriorates.

### —Intrinsic Viscosity—

The intrinsic viscosity (IV) of the polyester film according to the present invention is preferably from 0.6 to 1.3, and more preferably from 0.65 to 1.00, and still more preferably from 0.68 to 0.80.

If the IV is 0.6 or more, the molecular weight of the polyester is maintained in a desired range, and thus a good adhesion can be obtained without cohesive fracture at the adhesion interface. If the IV is 1.3 or less, the melt viscosity is good while manufacturing the film, and thus the thermal decomposition of the polyester induced by shear heating is suppressed, and therefore the acid value (AV) can be suppressed to a low level.

Meanwhile, the intrinsic viscosity (IV) refers to a value obtained by extrapolating a concentration to zero in a value obtained by dividing a specific viscosity (ηₛₚ=ηᵣ−1) obtained by subtracting one from the ratio ηᵣ between solution viscosity (η) and solvent viscosity (η₀) (=η/η₀; relative viscosity) by a concentration. The IV can be obtained from the viscosity of a solution of 25° C. obtained by dissolving a polyester resin in a mixed solvent of 1,1,2,2-tetrachloroethane/phenol (=2/3 [mass ratio]) using an Ubbelohde type viscometer.

—Terminal Carboxyl Groups Before and After Thermal Treatment—

In the polyester film according to the present invention, the increase in the concentration of terminal carboxyl groups after performing an 80-hour long thermal treatment under an environment of 120° C., 100% RH is preferably from 30 equivalents/ton to 65 equivalents/ton, and more preferably from 32 equivalents/ton to 60 equivalents/ton, and still more preferably from 33 equivalents/ton to 55 equivalents/ton.

If the increase in the concentration of terminal carboxyl groups before and after the thermal treatment is 30 equivalents/ton or more, adhesion is good in a long term weather resistance test, and if the increase is 65 equivalents/ton or less, hydrolysis resistance is excellent.

—Amount of OH at the Surface—

In the polyester film according to the present invention, the amount of OH groups at the film surface (hereinafter, referred to as ‘surface OH amount’) is preferably in a range of from 0.05 equivalents/m² to 0.3 equivalents/m², and more preferably from 0.08 equivalents/m² to 0.25 equivalents/m², and still more preferably from 0.12 equivalents/m² to 0.2 equivalents/m². When the surface OH amount is 0.05 equivalents/m² or more, the OH amount is secured, and the adhesion with a sealing material layer such as an EVA layer, or the adhesion between EVA and the polyester film, or the adhesion with an adhesion layer becomes good. When the surface OH amount is 0.3 equivalents/m² or less, the film surface is suppressed from being excessively hydrophilic, and water adsorption and the generation of hydrolysis are also suppressed, and it is possible to further improve the adhesion with an object by avoiding embrittlement or cohesive fracture induced by the generation of lower molecular weight polyester.

<Manufacturing Method of a Polyester Film>

Next, a manufacturing method of the polyester film according to the present invention will be described.

A manufacturing method of a polyester film according to the present invention includes:

cooling a molten film-shaped polyester extruded from an extrusion die at a rate of from 250° C./min to 800° C./min; and

performing a longitudinal stretching in a length direction with a stretching stress of from 5 MPa to 15 MPa and a stretch ratio of from 2.5 times to 4.5 times, and a transverse stretching in a width direction, on the cooled film-shaped polyester, so that a thickness of the polyester film after the longitudinal stretching and the transverse stretching becomes from 100 μm to 350 μm.

(Polyester)

Polyester that forms the polyester film according to the present invention can be obtained by performing an esterification reaction and/or an ester exchange reaction of (A) a dicarboxylic acid or an ester derivative thereof, such as aliphatic dicarboxylic acids, such as malonic acid, succinic acid, glutaric acid, adipic acid, suberic acid, sebacic acid, dodecanedioic acid, dimer acid, eicosanedioic acid, pimelic acid, azelaic acid, methylmalonic acid, and ethylmalonic acid; an alicyclic dicarboxylic acid such as adamantane dicarboxylic acid, norbornene dicarboxylic acid, isosorbide, cyclohexandicarboxylic acid, and decalindicarboxylic acid; an aromatic dicarboxylic acid, such as terephthalic acid, isophthalic acid, phthalic acid, 1,4-naphthalene dicarboxylic acid, 1,5-naphthalene dicarboxylic acid, 2,6-naphthalene dicarboxylic acid, 1,8-naphthalene dicarboxylic acid, 4,4′-diphenyldicarboxylic acid, 4,4′-diphenyletherdicarboxylic acid, 5-sodium sulfo isophthalic acid, phenylindan dicarboxylic acid, anthracene dicarboxylic acid, phenanthrene dicarboxylic acid, and 9,9′-bis(4-carboxyphenyl)fluorene acid and (B) a diol compound, such as aliphatic diols, such as ethylene glycol, 1,2-propanediol, 1,3-propanediol, 1, 4-butanediol, 1,2-butanediol, and 1,3-butanediol; an alicyclic diol, such as cyclohexanedimethanol, spiro glycol, and isosorbide; and aromatic diols, such as bisphenol A, 1,3-benzenedimethanol, 1,4-benzenedimethanol, and 9,9′-bis(4-hydroxyphenyl)fluorene using a known method.

As the dicarboxylic acid component, at least one kind of aromatic dicarboxylic acid is preferable. It is more preferable to include an aromatic dicarboxylic acid as a main component in the dicarboxylic acid component. Meanwhile, the “main component” refers to the fact that the ratio of an aromatic dicarboxylic acid in the dicarboxylic acid component is 80% by mass or more. Dicarboxylic acids other than the aromatic dicarboxylic acid may be included. Examples of the dicarboxylic acids include an ester derivative of, for example, an aromatic dicarboxylic acid.

As the diol component, at least one kind of aliphatic diol is preferable. As the aliphatic diol, ethyleneglycol can be included, and it is preferable to include ethyleneglycol as a main component. Meanwhile, the “main component” refers to the fact that the ratio of ethyleneglycol in the diol component is 80% by mass or more.

The preferable amount of an aliphatic diol (for example, ethyleneglycol) used is in a range of from 1.015 mol to 1.50 mol with respect to one mol of the aromatic dicarboxylic acid (for example, terephthalic acid) and an optional ester derivative thereof. The amount used is more preferably in a range of from 1.02 mol to 1.30 mol, and still more preferably in a range of from 1.025 mol to 1.10 mol. If the amount used is in a range of 1.015 mol or more, the esterification reaction proceeds satisfactorily, and if the amount used is in a range of 1.50 mol or less, generation of diethyleneglycol by the dimerization of ethyleneglycol and the like are suppressed, and therefore many properties such as melting point, glass transition temperature, crystallinity, heat resistance, hydrolysis resistance, and weather resistance can be maintained satisfactorily.

It is possible to use a conventionally-known reaction catalyst for esterification reaction or ester exchange reaction. Examples of the reaction catalyst can include an alkali metal compound, an alkali earth metal compound, a zinc compound, a lead compound, a manganese compound, a cobalt compound, an aluminum compound, an antimony compound, a titanium compound, and a phosphorous compound. Normally, it is preferable to add an antimony compound, a germanium compound, or a titanium compound as a polymerization catalyst in an arbitrary step before completing the manufacturing method of polyester. In such a method, if, for example, a germanium compound is taken as an example, it is preferable to add the germanium compound powder as it is.

For example, in an esterification reaction process, an aromatic dicarboxylic acid and an aliphatic diol are polymerized in the presence of a catalyst including a titanium compound. This esterification reaction process includes using an organic chelate titanium complex having an organic acid as a ligand as a titanium compound that is a catalyst, and further includes adding at least an organic chelate titanium complex, a magnesium compound, and a pentavalent phosphoric acid ester which does not have an aromatic ring as a substituent in this order.

First of all, in the beginning, an aromatic dicarboxylic acid and an aliphatic diol are mixed with a catalyst including an organic chelate titanium complex that is a titanium compound before adding a magnesium compound and a phosphorous compound. Since a titanium compound, such as an organic chelate titanium complex, has a high catalyst activity even with respect to esterification reaction, it is possible to perform esterification reaction satisfactorily. At this time, it is possible to add a titanium compound in the mixture of the dicarboxylic acid component and the diol component, or to mix the diol component (or the dicarboxylic acid component) after the dicarboxylic acid component (or the diol component) and a titanium compound are mixed. It is also possible to mix the dicarboxylic acid component, the diol component, and a titanium compound at the same time. The mixing method is not particularly limited, and a conventionally-known method can be used.

More preferable examples of polyester include polyethylene terephthalate (PET) and polyethylene-2,6-naphthalate (PEN), and a still more preferable example is PET. Furthermore, preferable examples of PET include PET polymerized by using one kind or two kinds or more of catalysts selected from a group consisting of germanium (Ge) catalysts, antimony (Sb) catalysts, aluminum (Al) catalysts, and titanium (Ti) catalysts, and Ti catalysts are more preferable.

The Ti catalysts have a high reaction activity, and thus can reduce the polymerization temperature. Therefore, in particular, the Ti catalysts can suppress thermal decomposition of PET and thus generation of COOH during a polymerization reaction, and therefore, in the polyester film according to the present invention, the Ti catalysts are preferable for adjusting the amount of terminal COOH in a predetermined range.

Examples of the Ti catalysts can include an oxide, a hydroxide, an alkoxide, a carboxylic acid salt, a carbonate, an oxalate, an organic chelate titanium complex, and a halide. The Ti catalysts may be used in combination of two kinds or more of titanium compounds as long as they do not deteriorate the effects of the present invention.

Examples of the Ti catalysts can include a titanium alkoxide, such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, and tetrabenzyl titanate, a titanium oxide obtained by the hydrolysis of a titanium alkoxide, a titanium-silicon or zirconium composite oxide obtained by the hydrolysis of a mixture of a titanium alkoxide and a silicon alkoxide or a zirconium alkoxide, titanium acetate, titanium oxalate, potassium titanium oxalate, sodium titanium oxalate, potassium titanate, sodium titanate, a mixture of titanic acid and aluminum hydroxide, titanium chloride, a mixture of titanium chloride and aluminum chloride, titanium acetylacetonate, and an organic chelate titanium complex having an organic acid as a ligand.

For manufacturing a PET by polymerization using a Ti catalyst, it is possible to use a polymerization method described in, for example, JP-A No. 2005-340616, JP-A No. 2005-239940, JP-A No. 2004-319444, Japanese Patent No. 3436268, Japanese Patent No. 3979866, Japanese Patent No. 3780137, and JP-A No. 2007-204538.

When polymerizing polyester, it is preferable to perform polymerization using a titanium (Ti) compound as a catalyst in an amount of Ti element of from 1 ppm to 30 ppm, and more preferably from 2 ppm to 20 ppm, and still more preferably from 3 ppm to 15 ppm. In this case, the polyester film according to the present invention includes titanium in a range of from 1 ppm to 30 ppm.

If the amount is 1 ppm or more, a preferable IV can be obtained, and if the amount is 30 ppm or less, terminal COOH can be adjusted to satisfy the above range.

For the synthesis of polyester using the Ti compounds, it is possible to apply the methods described in, for example, Japanese Examined Patent Application (JP-B) No. 8-30119, Japanese Patent No. 2543624, Japanese Patent No. 3335683, Japanese Patent No. 3717380, Japanese Patent No. 3897756, Japanese Patent No. 3962226, Japanese Patent No. 3979866, Japanese Patent No. 3996871, Japanese Patent No. 4000867, Japanese Patent No. 4053837, Japanese Patent No. 4127119, Japanese Patent No. 4134710, Japanese Patent No. 4159154, Japanese Patent No. 4269704, and Japanese Patent No. 4313538.

(Titanium compound)

As a titanium compound which is a catalyst component, at least one kind of an organic chelate titanium complex having an organic acid as a ligand is used. Examples of the organic acid can include citric acid, lactic acid, trimellitic acid, and malic acid. Among them, an organic chelate complex having citric acid or a citric salt as a ligand is preferable.

For example, in the case of using a chelate titanium complex having citric acid as a ligand, only a small amount of foreign substances, such as fine particles, are generated, and compared with other titanium compounds, a polyester resin having a satisfactory polymerization activity and color tone can be obtained. Furthermore, in the case of using a citric acid chelate titanium complex, a polyester resin having a satisfactory polymerization activity and color tone and a small amount of terminal carboxyl groups can be obtained by adding the complex in the esterification reaction step, compared with the case of adding the complex after esterification reaction. Regarding this point, it is assumed that, since a titanium catalyst has a catalyst effect in the esterification reaction, the acid value of an oligomer after the completion of esterification reaction is decreased by adding the complex in the esterification step, and therefore the subsequent condensation polymerization reaction is performed more efficiently; and that a complex having a citric acid as a ligand has a strong hydrolysis resistance, compared with, for example, a titanium alkoxide, and therefore hydrolysis does not occur during an esterification reaction process, so that the titanium catalyst can effectively act as a catalyst for esterification reaction and condensation polymerization reaction while maintaining its intrinsic activity.

It is known that, generally, as the amount of terminal carboxyl groups increases, hydrolysis resistance deteriorates, but since the amount of terminal carboxyl groups is decreased by the adding method according to the present invention, improvement in hydrolysis resistance is expected.

The citric acid chelate titanium complex can be easily obtained from a commercially available product, such as VERTEC AC-420, trade name, manufactured by Johnson Matthey.

The aromatic dicarboxylic acid and the aliphatic diol can be introduced by preparing a slurry including them and continuously supplying the slurry to the esterification reaction process.

In a preferable embodiment, during esterification reaction, a Ti catalyst is used in an amount of Ti element of from 1 ppm to 30 ppm, and more preferably from 3 ppm to 20 ppm, and still more preferably from 5 ppm to 15 ppm for polymerization reaction. If the amount of Ti added is 1 ppm or more, it is advantageous in that the polymerization rate becomes fast, and if the amount added is 30 ppm or less, it is advantageous in that satisfactory color tone can be obtained.

Examples of titanium compounds other than an organic chelate titanium complex can include, generally, an oxide, a hydroxide, an alkoxide, a carboxylic acid salt, a carbonate, an oxalate, and a halide. Other titanium compounds may be used together with an organic chelate titanium complex as long as they do not impair the effects of the present invention.

Examples of the titanium compounds can include a titanium alkoxide, such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, and tetrabenzyl titanate, a titanium oxide obtained by the hydrolysis of a titanium alkoxide, a titanium-silicon or zirconium composite oxide obtained by the hydrolysis of a mixture of a titanium alkoxide and a silicon alkoxide or a zirconium alkoxide, titanium acetate, titanium oxalate, potassium titanium oxalate, sodium titanium oxalate, a potassium titanate, a sodium titanate, a mixture of a titanic acid and an aluminum hydroxide, a titanium chloride, a mixture of a titanium chloride and an aluminum chloride, and titanium acetylacetonate.

For the synthesis of polyester using such titanium compounds, it is possible to apply the methods described in, for example, Japanese Examined Patent Application Publication (JP-B) No. 8-30119, Japanese Patent No. 2543624, Japanese Patent No. 3335683, Japanese Patent No. 3717380, Japanese Patent No. 3897756, Japanese Patent No. 3962226, Japanese Patent No. 3979866, Japanese Patent No. 3996871, Japanese Patent No. 4000867, Japanese Patent No. 4053837, Japanese Patent No. 4127119, Japanese Patent No. 4134710, Japanese Patent No. 4159154, Japanese Patent No. 4269704, and Japanese Patent No. 4313538.

In the present invention, it is preferable to prepare a polyester resin by a manufacturing method of a polyester resin including: an esterification reaction step which includes at least polymerizing an aromatic dicarboxylic acid and an aliphatic diol in the presence of a catalyst containing a titanium compound including an organic chelated titanium complex having an organic acid as a ligand, and adding the organic chelated titanium complex, a magnesium compound, and a pentavalent phosphoric acid ester which does not have an aromatic ring as a substituent, in this order; and a condensation polymerization step of subjecting an esterification reaction product produced by the esterification reaction step to a condensation polymerization reaction to produce a condensation polymerization product.

In this case, since an order of addition of adding an organic chelated titanium complex as a titanium compound, adding a magnesium compound, and then adding a specific pentavalent phosphorus compound is employed in the process of the esterification reaction, the reaction activity of the titanium catalyst can be maintained to be appropriately high, the electrostatic applicability can be imparted by magnesium, and the decomposition reaction in the condensation polymerization can be effectively suppressed. Therefore, as a result, a polyester resin is obtained which has less coloration and high electrostatic applicability, and exhibits an improvement in yellowing during exposure to high temperature.

Thereby, a polyester resin can be provided which undergoes less coloration during polymerization and during the subsequent melt film forming, so that the yellow tinge is reduced as compared with the conventional polyester resins obtained by antimony (Sb) catalyst systems, which has a color tone and transparency that are comparable to those of the relatively highly transparent polyester resins obtained by germanium catalyst systems, and which has excellent heat resistance. Furthermore, a polyester resin having high transparency and a reduced yellow tinge can be obtained without using a color adjusting material such as a cobalt compound or a colorant.

This polyester resin can be used for applications where the demand for transparency is high (for example, optical films and industrial lith films), and since there is no need to use expensive germanium-based catalysts, a significant reduction in cost can be made. In addition, because the incorporation of catalyst-induced foreign matter that is easily generated in Sb catalyst systems can also be avoided, the occurrence of failure during the film forming process and quality defects are also reduced, so that cost reduction as a result of yield improvement can be made.

For carrying out the esterification reaction, a process of adding an organic chelated titanium complex, which is a titanium compound, and a magnesium compound and a pentavalent phosphorus compound as additives, in this order, is provided. At this time, the esterification reaction proceeds in the presence of the organic chelated titanium complex, and then the magnesium compound is added before the addition of the phosphorus compound.

(Phosphorus Compound)

As the pentavalent phosphorus compound, at least one pentavalent phosphoric acid ester which does not have an aromatic ring as a substituent is used. Examples of the pentavalent phosphoric acid ester according to the invention include trimethyl phosphate, triethyl phosphate, tri-n-butyl phosphate, trioctyl phosphate, tris(triethylene glycol)phosphate, methyl acid phosphate, ethyl acid phosphate, isopropyl acid phosphate, butyl acid phosphate, monobutyl phosphate, dibutyl phosphate, dioctyl phosphate, and triethylene glycol acid phosphate.

Among the pentavalent phosphoric acid esters described above, a phosphoric acid ester having a lower alkyl group having 2 or fewer carbon atoms as a substituent [(OR)₃—P═O; R=alkyl group having 1 or 2 carbon atoms] is preferable, and specifically, trimethyl phosphate and triethyl phosphate are particularly preferable.

Particularly, in the case of using, as a catalyst, a chelated titanium complex having citric acid or a salt thereof as a ligand, a pentavalent phosphoric acid ester leads to a satisfactory polymerization activity and color tone as compared with a trivalent phosphoric acid ester, and in a case in which a pentavalent phosphoric acid ester having 2 or fewer carbon atoms is added, the balance between polymerization activity, color tone and heat resistance can be particularly improved.

The addition amount of the phosphorus compound is preferably an amount that corresponds to a content of P element of from 50 ppm to 90 ppm. The addition amount of the phosphorus compound is more preferably an amount that corresponds to a content of P element of from 60 ppm to 80 ppm, and even more preferably from 65 ppm to 75 ppm.

(Magnesium Compound)

When a magnesium compound is included, electrostatic applicability is enhanced.

In this case, coloration is likely to occur; however, according to the invention, coloration is suppressed, and thus excellent color tone and heat resistance can be obtained.

Examples of the magnesium compound include magnesium salts such as magnesium oxide, magnesium hydroxide, magnesium alkoxide, magnesium acetate, and magnesium carbonate. Among them, from the viewpoints of solubility in ethylene glycol, magnesium acetate is most preferable.

In order to impart high electrostatic applicability, the addition amount of the magnesium compound is preferably an amount that corresponds to a content of Mg element of 50 ppm or greater, and more preferably from 50 ppm to 100 ppm. The addition amount of the magnesium compound is, from the viewpoints of imparting electrostatic applicability, preferably an amount that corresponds to a content of Mg element of from 60 ppm to 90 ppm, and even more preferably from 70 ppm to 80 ppm.

In the esterification reaction step according to the invention, it is particularly preferable to add the titanium compound as the catalyst component and the magnesium compound and phosphorus compound as the additives such that the value Z calculated from the following formula (i) satisfies the following formula (ii) to carry out melt polymerization. Here, the P content is the amount of phosphorus originating from the entirety of phosphorus compounds including the pentavalent phosphoric acid ester which does not have an aromatic ring, and the Ti content is the amount of titanium originating from the entirety of Ti compounds including the organic chelated titanium complex. As such, when a combination of a magnesium compound and a phosphorus compound is selected and used in a catalyst system containing a titanium compound, and the timing of addition and the proportion of addition are controlled, a color tone with less yellow tinge is obtained while the catalytic activity of the titanium compound is maintained to be appropriately high. Thus, a heat resistance can be imparted that does not easily cause yellowing even if the polyester resin is exposed to high temperature during the polymerization reaction or during the subsequent film forming process (during melting).

Z=5×(P content [ppm]/atomic weight of P)−2×(Mg content [ppm]/atomic weight of Mg)−4×(Ti content [ppm]/atomic weight of Ti) (i)

0≦Z≦+5.0 (ii)

Since the phosphorus compound interacts with the titanium compound as well as the magnesium compound, this value is an index that quantitatively expresses the balance between the three components.

The formula (i) expresses the amount of phosphorus capable of acting on titanium, by subtracting the portion of phosphorus that acts on magnesium, from the total amount of phosphorus capable of reacting. In a case in which the value Z is positive, the system is in a state in which the phosphorus that inhibits titanium is in excess. In a case in which the value is negative, the system is in a state in which phosphorus that is required to inhibit titanium is insufficient. In regard to the reaction, since the respective atoms of Ti, Mg and P are not of equal valence, each of the mole numbers in the formula is weighted by multiplying by the valence.

In the invention, a polyester resin excellent in color tone and resistance to heat coloration can be obtained, while having a reaction activity necessary for the reaction, by using a titanium compound, a phosphorus compound and a magnesium compound that do not require special synthesis or the like and are easily available at low cost.

In the formula (ii), from the viewpoints of further enhancing the color tone and the resistance to heat coloration while maintaining the polymerization reactivity, it is preferable that +1.0≦Z≦+4.0 is satisfied, and it is more preferable that +1.5≦Z≦+3.0 is satisfied.

In a preferable embodiment according to the invention, a chelated titanium complex having citric acid or a citric acid salt as a ligand is added in an amount of Ti element of from 1 ppm to 30 ppm to the aromatic dicarboxylic acid and the aliphatic diol before the esterification reaction is completed, and then in the presence of the chelated titanium complex, a magnesium salt of weak acid is added in an amount of Mg element of from 60 ppm to 90 ppm (more preferably, from 70 ppm to 80 ppm), and after the addition, a pentavalent phosphoric acid ester which does not have an aromatic ring as a substituent is further added in an amount of P element of from 60 ppm to 80 ppm (more preferably, from 65 ppm to 75 ppm).

The esterification reaction can be carried out by using a multistage type apparatus having at least two reactors connected in series under the conditions in which ethylene glycol is refluxed, while removing the water or alcohol generated by the reaction from the system.

The esterification reaction may be carried out in a single step, or may be carried out by division into multiple stages.

In a case in which the esterification reaction is carried out in a single step, the esterification reaction temperature is preferably 230° C. to 260° C., and more preferably 240° C. to 250° C.

In a case in which the esterification reaction is carried out by division into multiple stages, the temperature of the esterification reaction at the first reaction tank is preferably 230° C. to 260° C., and more preferably 240° C. to 250° C., and the pressure is preferably 1.0 kg/cm² to 5.0 kg/cm², and more preferably 2.0 kg/cm² to 3.0 kg/cm². The temperature of the esterification reaction at the second reaction tank is preferably 230° C. to 260° C., and more preferably 245° C. to 255° C., and the pressure is preferably 0.5 kg/cm² to 5.0 kg/cm², and more preferably 1.0 kg/cm² to 3.0 kg/cm². Furthermore, in a case in which the esterification reaction is carried out by division into three or more stages, the conditions for the esterification reaction in the middle stages are preferably established to be intermediate between the conditions at the first reaction tank and the conditions at the final reaction tank.

—Condensation Polymerization—

In the condensation polymerization, a condensation polymerization product is produced by a condensation polymerization reaction of the esterification reaction product produced in the esterification reaction.

The condensation polymerization reaction may be carried out in a single stage, or may be carried out by division into multiple stages.

The esterification reaction product such as oligomers produced in the esterification reaction is continuously subjected to a condensation polymerization reaction. This condensation polymerization reaction can be preferably carried out by supplying the esterification reaction product to condensation polymerization reaction tanks of multiple stages.

For example, the condensation polymerization reaction conditions, in the case of performing the reaction in a three-stage reaction tank, are that the reaction temperature at the first reaction tank is preferably 255° C. to 280° C., and more preferably 265° C. to 275° C., and the pressure is preferably 100 torr to 10 ton (13.3×10⁻³ MPa to 1.3×10⁻³ MPa), and more preferably 50 ton to 20 ton (6.67×10⁻³ MPa to 2.67×10⁻³ MPa). The reaction temperature at the second reaction tank is preferably 265° C. to 285° C., and more preferably 270° C. to 280° C., and the pressure is preferably 20 ton to 1 ton (2.67×10⁻³ MPa to 1.33×10⁻⁴ MPa), and more preferably 10 ton to 3 ton (1.33×10⁻³ MPa to 4.0×10⁻⁴ MPa). In the third and final reaction tank, the reaction temperature is preferably 270° C. to 290° C., and more preferably 275° C. to 285° C., and the pressure is preferably 10 ton to 0.1 ton (1.33×10⁻³ MPa to 1.33×10⁻⁵ MPa) and more preferably 5 ton to 0.5 ton (6.67×10⁻⁴ MPa to 6.67×10⁻⁵ MPa).

In the invention, when the esterification reaction step and condensation polymerization step as described above are provided, a polyester resin composition containing titanium atoms (Ti), magnesium atoms (Mg) and phosphorus atoms (P), in which the value Z calculated from the following formula (i) satisfies the following formula (ii), can be produced.

Z=5×(P content [ppm]/atomic weight of P)−2×(Mg content [ppm]/atomic weight of Mg)−4×(Ti content [ppm]/atomic weight of Ti) (i)

0≦Z≦+5.0 (II)

When the polyester resin composition satisfies 0≦Z≦+5.0, the balance between the three elements of Ti, P and Mg is appropriately regulated, and therefore, the polyester resin has an excellent color tone and heat resistance (reduction of yellowing under high temperature) and can maintain high electrostatic applicability, while maintaining the polymerization reactivity. Furthermore, according to the invention, a polyester resin having high transparency and reduced yellow tinge can be obtained without using a color adjusting material such as a cobalt compound or a colorant.

The formula (i) quantitatively expresses the balance between the three components of the titanium compound, magnesium compound and phosphorus compound, and represents the amount of phosphorus capable of acting on titanium, by subtracting the portion of phosphorus that acts on magnesium from the total amount of phosphorus capable of reaction. If the value Z is less than 0, that is, if the amount of phosphorus that acts on titanium is too small, the catalytic activity (polymerization reactivity) of titanium is increased. However, heat resistance is decreased, and the polyester resin thus obtained takes on a yellow tinge. Thus, the polyester resin is colored after polymerization, for example, during film forming (during melting), and the color tone is deteriorated. Furthermore, if the value Z exceeds +5.0, that is, if the amount of phosphorus that acts on titanium is too large, the heat resistance and color tone of the polyester resin thus obtained are satisfactory, but the catalytic activity is excessively decreased, and producibility is deteriorated.

In the invention, due to the same reasons as described above, the formula (ii) preferably satisfies 1.0≦Z≦4.0, and more preferably satisfies 1.5≦Z≦3.0.

The measurement of the respective elements of Ti, Mg and P can be carried out by quantifying the respective elements in the polyester (PET) by using a high resolution type high resolution inductively coupled plasma mass spectrometer (HR-ICP-MS; trade name, AttoM, manufactured by SII Nanotechnology, Inc.), and calculating the contents [ppm] from the results thus obtained.

Furthermore, it is preferable that the produced polyester resin composition further satisfies the following formula (iii).

b value when fabricated into pellets after condensation polymerization 4.0 (iii)

If the b value of the pellets is 4.0 or less when the polyester resin obtained by condensation polymerization is pelletized, the polyester resin has a reduced yellow tinge and excellent transparency. When the b value is 3.0 or less, the polyester resin has a color tone comparable to that of polyester resins polymerized in the presence of Ge catalysts.

The b value serves as an index representing the color tinge, and is a value measured by using ND-101D (trade name, manufactured by Nippon Denshoku Industries Co., Ltd.).

It is also preferable that the polyester resin composition satisfies the following formula (iv).

Rate of color tone change [Δb/minute]≦0.15 (iv)

If the rate of color tone change [Δb/minute] is 0.15 or less when the pellets of the polyester resin obtained by condensation polymerization are retained in a molten state at 300° C., the yellowing when the polyester resin is exposed to heat can be suppressed. Thereby, in the case of, for example, forming a film by extruding with an extruder, a film having less yellowing and an excellent color tone can be obtained.

The rate of color tone change is preferably a smaller value, and a value of 0.10 or less is particularly preferable.

The rate of color tone change serves as an index representing a change in color due to heat, and is a value determined by the method described below.

That is, pellets of the polyester resin composition are fed into a hopper of an injection molding machine (for example, EC100NII, trade name, manufactured by Toshiba Machine Co., Ltd.), and while the polyester resin is retained in a molten state inside the cylinder (300° C.) and the retention time is changed, the polyester resin is molded into a plate form. The b value of the plate at this time is measured using ND-101D (trade name, manufactured by Nippon Denshoku Co., Ltd.). The rate of change [Δb/minute] is calculated based on the changes in the b value.

(Additives)

The polyester according to the present invention can further include additives, such as a light stabilizer, an antioxidant, an ultraviolet absorbent, a flame retardant, a lubricant (fine particles), a nucleation agent (crystallization agent), and an anti crystallization agent.

The polyester film according to the present invention preferably includes a light stabilizer. By including a light stabilizer, ultraviolet degradation can be prevented. Examples of the light stabilizer can include a compound that absorbs rays such as ultraviolet rays and converts them into heat energy, and a material that captures radicals generated when a film or the like absorbs light and decomposes to control decomposition chain reactions.

Preferable examples of the light stabilizer include a compound that absorbs rays, such as ultraviolet rays, and converts them into heat energy. By including such a light stabilizer in the film, even when irradiated with ultraviolet rays continuously for a long period of time, improved effect of partial discharge voltage of the film can be maintained at a high level for a long time, and color tone change and strength degradation of the film by ultraviolet rays can be prevented.

For example, as an ultraviolet absorbent, it is possible to preferably use, without any particular limitation, any one of an organic ultraviolet absorbent, an inorganic ultraviolet absorbent, and the concurrent use thereof as long as it does not impair other characteristics of the polyester. Meanwhile, it is desirable that an ultraviolet absorbent be excellent in terms of humidity and heat resistance and be dispersed uniformly in the film.

Examples of the ultraviolet absorbent can include, as an organic ultraviolet absorbent, triazine, salicylic acid, benzophenone, benzotriazole and cyanoacrylate ultraviolet absorbents, and an ultraviolet stabilizer, such as hindered amine compounds. Specific examples can include a salicylic acid compound, such as p-t-butyl phenyl salicylate and p-octylphenyl salicylate; benzophenone compounds, such as 2,4-dihydroxy benzophenone, 2-hydroxy-4-methoxy benzophenone, 2-hydroxy-4-methoxy-5-sulfobenzophenone, 2,2′,4,4′-tetrahydroxy benzophenone, bis(2-methoxy-4-hydroxy-5-benzoylphenyl)methane, benzotriazole compounds, such as 2-(2′-hydroxy-5′-methylphenyl)benzotriazole, 2-(2′-hydroxy-5′-methylphenyl)benzotriazole, 2,2′-methylene bis[4-(1,1,3,3-tetramethylbutyl)-6-(2H benzotriazol-2-yl)phenol], cyanoacrylate compounds, such as ethyl-2-cyano-3,3′-diphenylacrylate); triazine compounds such as 2-(4,6-diphenyl-1,3,5-triazin-2-yl)-5-[(hexyl)oxy]-phenol; hindered amine compounds such as bis(2,2,6,6-tetramethyl-4-pyperidyl)sebacate, dimethyl succinate·1-(2-hydroxyethyl)-4-hydroxy-2,2,6,6-tetramethylpiperidine polycondensate, and nickel bis(octylphenyl)sulphide, and 2,4-di·t-butylphenyl-3′,5′-di·t-butyl-4′-hydroxy benzoate, 2,2′-p-phenylene bis(3,1-benzo oxazin-4-one), 2,2′-(4,4′-diphenylene)bis(3,1-benzo oxazin-4-one), and 2,2′-(2,6-naphthylene)bis(3,1-benzo oxazin-4-one).

Among these ultraviolet absorbents, in terms of a high resistance with respect to the repeated absorption of ultraviolet, a triazine ultraviolet absorbent is more preferable. Meanwhile, these ultraviolet absorbents may be added to the film as the above-described ultraviolet absorbent alone or introduced in a form of copolymerizing a monomer having an ultraviolet absorbing function in an organic conductive material or a water-insoluble resin.

The content of the light stabilizer in the polyester film is preferably from 0.1% by mass to 10% by mass with respect to the total mass of the polyester film, and more preferably from 0.3% by mass to 7% by mass, and still more preferably from 0.7% by mass to 4% by mass. Thereby, it is possible to suppress a decrease in the molecular weight of the polyester due to photo degradation over a long time and thus to suppress a decrease in an adhesion force induced by cohesive fracture in the film which is caused by the decrease in the molecular weight.

Furthermore, the polyester film according to the present invention can include, in addition to the light stabilizer, additives, such as an ultraviolet absorbent, a flame retardant, fine particles, a nucleation agent (crystallization agent), and an anti crystallization agent. Examples of the fine particles can include inorganic particles, such as titanium dioxide, calcium carbonate, silica, kaolin, talc, alumina, barium sulfate, calcium fluoride, lithium fluoride, zeolite, and molybdenum sulfide; organic particles, such as crosslinked polymer particles and calcium oxalate; and precipitate particles generated during the polymerization of the polyester. Preferable examples are titanium dioxide, silica, and calcium carbonate.

In the present invention, as a raw material (polyester) when manufacturing a polyester film, it is preferable to use solid-phase polymerized pellets.

Solid-phase polymerization can be preferably performed using small pieces, such as pellets, of the polyester polymerized by the above-mentioned esterification reaction or commercially available polyester. The solid-phase polymerization is preferably performed in a condition of a temperature of from 150° C. to 250° C., more preferably from 170° C. to 240° C., and still more preferably from 180° C. to 230° C. and a time of from 1 hour to 50 hours, more preferably from 5 hours to 40 hours, and still more preferably from 10 hours to 30 hours. The solid-phase polymerization is preferably performed under vacuum or in a nitrogen flow.

By performing the solid-phase polymerization after polymerization, it is possible to respectively control the moisture content and degree of crystallinity of the polyester film, the concentration of terminal carboxyl groups (AV) and intrinsic viscosity (IV) in the present invention in the above ranges. By using a solid-phase polymerized polyester resin, each of the moisture content and degree of crystallinity of the obtained polyester film can be easily achieved in the above ranges with the film manufacturing method according to the present invention.

The solid-phase polymerization may be performed by a continuous method (a method that fills a resin in a tower, and heats and retains it slowly for a predetermined time, and then eject it sequentially) or a batch method (a method that feeds a resin in a vessel and heats it for a predetermined time). Specifically, as the solid-phase polymerization, methods described in, for example, Japanese Patent No. 2621563, Japanese Patent No. 3121876, Japanese Patent No. 3136774, Japanese Patent No. 3603585, Japanese Patent No. 3616522, Japanese Patent No. 3617340, Japanese Patent No. 3680523, Japanese Patent No. 3717392, and Japanese Patent No. 4167159 can be used.

The temperature of the solid-phase polymerization is preferably from 170° C. to 240° C., and more preferably from 180° C. to 230° C., and still more preferably from 190° C. to 220° C. Temperature in the above ranges is preferable from the standpoint of further highly reducing the concentration of terminal carboxyl groups (AV). The time of the solid-phase polymerization is preferably from 5 hours to 100 hours, and more preferably from 10 hours to 75 hours, and still more preferably from 15 hours to 50 hours. The above time is preferable from the standpoint of easily controlling the concentration of terminal carboxyl groups (AV) and the intrinsic viscosity (IV) in the preferable ranges of the present invention. The solid-phase polymerization is preferably performed under vacuum or in a nitrogen flow.

The manufacturing method of the polyester film according to the present invention includes an extrusion process that includes extruding a raw material polyester from an extrusion die and cooling a molten film-shaped polyester (melt) at a rate of from 250° C./min to 800° C./min, and a stretching process that includes performing on the cooled film-shaped polyester a longitudinal stretching in a length direction (film manufacturing direction) with a stretching stress of from 5 MPa to 15 MPa and a stretch ratio of from 2.5 times to 4.5 times and a transverse stretching in a width direction, so that a thickness of the polyester film after the stretching process becomes from 100 μm to 350 μm.

Meanwhile, before the extrusion process, a solid-phase polymerization process that includes solid-phase polymerizing polyester as described in the above may be further provided, and an esterification reaction process that includes performing an esterification reaction and/or ester exchange reaction for synthesizing polyester may be further provided, and separately and previously synthesized polyester, for example, commercially available polyester may be used in the solid-phase polymerization process.

The manufacturing method of the polyester film according to the present invention preferably further includes a synthesis process that includes synthesizing polyester to be used in the solid-phase polymerization process by esterifying a dicarboxylic acid or an ester derivative thereof and a diol compound in the presence of a titanium catalyst. Meanwhile, the details and the preferable embodiments of the dicarboxylic acid and the ester derivative thereof, the diol compound, and the titanium catalyst are as described above.

(1) Extrusion Process

Polyester is kneaded in a molten state and a molten film-shaped polyester extruded from an extrusion die (nozzle plate) is cooled at a rate of from 250° C./min to 800° C./min.

For example, it is possible to melt polyester using an extruder after drying the polyester obtained from the above-mentioned solid-phase polymerization process and reducing residual moisture to be 100 ppm or less. The melting point is preferably from 250° C. to 320° C., and more preferably from 260° C. to 310° C., and still more preferably from 270° C. to 300° C. The extruder may be either uniaxial or multiaxial. From the standpoint of further suppressing generation of terminal COOH due to thermal decomposition, it is more preferable to replace the inside of the extruder with nitrogen.

The molten resin (melt) is extruded from the extrusion die through, for example, a gear pump and a filter. At this time, the molten resin may be extruded into a single layer or multiple layers.

The thickness of the molten film-shaped polyester (melt) extruded from the die is preferably from 2 mm to 6 mm, and more preferably from 2.5 mm to 5 mm, and still more preferably from 3 mm to 4.5 mm. As in the present invention, by making the thickness of the melt thick, the necessary time for the extruded melt to be cooled down to a glass transition temperature (Tg) or less can be lengthened. During the lengthened necessary time, OH groups or COOH groups in the polyester are diffused in the polyester.

If the thickness of the melt is 6 mm or less, a cooling rate of from 250° C./min to 800° C./min is achieved after extrusion, and if the thickness is 2 mm or more, it is possible to obtain a biaxially stretched film of the polyester having a thickness of 100 μm or more even when a stretch ratio is increased in the stretching process after cooling. The cooling rate of the present invention can be obtained by performing forced cooling and solidification with a cooling cast drum and an auxiliary cooling apparatus (an apparatus that blows a cooling air to the melt film-shaped polyester) disposed opposite to the cooling cast drum. It is possible to use auxiliary cooling apparatuses described in, for example, JP-A No. 7-266406, JP-A No. 9-204004, and JP-A No. 2006-281531. Auxiliary cooling apparatuses, such as a water mist spry type apparatus, a mist spray type apparatus, and a water tank, can be used.

In the case of extruding a molten film-shaped resin (melt) from a die, it is preferable to adjust a shear rate during extrusion in a desirable range. The shear rate during extrusion is preferably from 1 s⁻¹ to 300 s⁻¹, and more preferably from 10 s⁻¹ to 200 s⁻¹, and still more preferably from 30 s⁻¹ to 150 s⁻¹. Thereby, when extruding the resin from the die, die swell (a phenomenon in which a melt expands in the thickness direction) occurs. That is, since a stress works in the thickness direction (the normal line direction to the film), molecular movement is accelerated in the thickness direction of the melt.

If the shear rate is 1 s⁻¹ or more, it is possible to sufficiently tuck COOH groups or OH groups into the inside of the melt, and if the shear rate is 300 s⁻¹ or less, COOH groups and OH groups on the film surface can satisfy the above mentioned ranges of the surface COOH group amount and the surface OH group amount.

Due to the influence of die swell induced by the extrusion of the molten resin (melt) in such a high shear rate, it is highly likely that the melt will contact the die lips and thus easily generate die lines. This problem can be dealt with by providing a variation (pulsation) of preferably from 0.1% to 5%, and more preferably from 0.3% to 4%, and still more preferably from 0.5% to 3% to the extrusion amount of the melt.

That is, the amount of die swell varies according to the variation. That is, since it is possible to control a period of time during which the molten resin (melt) contacts the die, continuous die lines are not generated. Within these ranges, an increase in deformation arising from thickness variation can be suppressed. If the die lines are intermittent, they can be solved by the viscous effect of the melt, and therefore unlikely to be a problem in practice. Furthermore, such a variation in die swell varies the stress in the thickness direction, thereby bringing about an effect to accelerate the movement of COOH or OH.

This variation of the extrusion amount may be made by varying the rotation amount of a screw in the extruder or by providing a gear pump between the extruder and the die and varying the rotation number thereof.

The melt extruded from the extrusion die can be solidified at a rate of from 250° C./min to 800° C./min using a chilled roll (a cooling cast drum) and an auxiliary cooling apparatus disposed opposite to the cooling cast drum. By accelerating cooling by blowing a cooling air from the opposite face of the chilled roll or contacting a cooling roll, even a thick molten film (in more detail, a film having a thickness before stretching of 2.0 mm or more and a thickness after stretching of 100 μm or more, and furthermore, 255 μm or more) can be cooled effectively, and therefore it is possible to perform rapid cooling at the above-mentioned cooling rate.

At this time, the temperature of the chilled roll is preferably from −10° C. to 30° C., and more preferably from −5° C. to 25° C., and still more preferably from 0° C. to 15° C. Furthermore, from the viewpoints of increasing adhesion between the melt and the chilled roll so that the cooling efficiency increases, it is preferable to apply static electricity before the melt contacts the chilled roll. The surface temperature can be adjusted to a predetermined temperature by flowing a refrigerant inside the cast drum.

Meanwhile, in the case of an insufficient cooling, it is highly likely that spherocrystals will be generated, and these spherocrystals cause stretching variation, thus causing thickness variation.

When manufacturing a thick film, cooling rate on the cast (cooling) drum decreases, and thus spheocrystals are generated, and therefore it is highly likely that stretching variation will occur.

However, this problem can be solved by providing the cast drum with a temperature variation of from 0.1° C. to 5° C., and more preferably from 0.3° C. to 4° C., and still more preferably from 0.5° C. to 3° C.

Here, temperature variation refers to a difference between the highest temperature and the lowest temperature when the temperature of the cast drum is measured along the drum width direction.

If a temperature difference exists as such, a temperature difference is generated in the melt on the cast drum, and therefore extensional/shrinkage stress works on the melt. When the melt contacts the cast drum, a temperature variation is generated due to the involvement of an air layer, but if a temperature variation is provided in the above range, the melt is extended/shrunk so that the air layer is excluded, and therefore adhesion is promoted, and cooling is promoted. On the other hand, it is not preferable to provide a temperature variation exceeding the above range, since it generates a shrinkage variation induced by a cooling temperature variation that occurs during casting, and thus deformation is generated in the cast film.

Such a temperature distribution can be induced on the cast drum by developing a temperature variation by providing a baffle plate inside the drum and then flowing a heat medium therethrough so as to disturb the passage.

The cast (not stretched) film obtained in the above manner is biaxially stretched in the below-mentioned manner so as to have a thickness of from 100 μm to 350 μm, and preferably from 255 μm to 350 μm, and more preferably from 260 μm to 340 μm.

During the time from extruding the melt (the molten resin) from the die to contacting with the cooling roll (air gap), it is preferable to adjust humidity to be from 5% RH to 60% RH, and more preferably from 10% RH to 55% RH, and still more preferably from 15% RH to 50% RH.

By controlling the humidity in the air gap within the above ranges, the surface carboxylic acid amount or the surface OH amount can be adjusted.

That is, as described in the above, by adjusting the hydrophobic property of air, it is possible to adjust the tucking of COOH groups or OH groups from the film surface.

At this time, the surface OH amount and the surface carboxylic acid amount increase at a high humidity and the surface OH amount and the surface carboxylic acid amount decrease at a low humidity.

This air gap effect particularly affects the surface COOH amount. This is because COOH groups have a higher polarization than OH groups and are easily affected by the humidity in the air gap.

In an extrusion in such a low humidity, adhesion to the cast (cooling) drum decreases, and a cooling variation is easily generated, but such a cooling variation can be reduced by providing a temperature distribution of from 0.1° C. to 5° C. to the cast roll.

(2) Stretching Process

The stretching process of the present invention is a biaxial stretching process that includes performing a longitudinal stretching in a length direction with a stretching stress of from 5 MPa to 15 MPa and a stretch ratio of from 2.5 times to 4.5 times and a transverse stretching in the width direction on the film-shaped polyester (not stretched film) extruded from the die in the extrusion process and cooled, so that the thickness of the film after the biaxial stretching becomes from 100 μm to 350 μm.

Specifically, the unstretched polyester film is introduced into a roll group heated to a temperature of from 70° C. to 120° C., and then longitudinally stretched in the length direction (the length direction, that is, a film proceeding direction) with a stretching stress of from 5 MPa to 15 MPa and a stretch ratio of from 2.5 times to 4.5 times, and more preferably with a stretching stress of from 8 MPa to 14 MPa and a stretch ratio of from 3.0 times to 4.0 times. After the longitudinal stretching, it is preferable to cool the film at the roll group with a temperature of from 20° C. to 50° C.

It is preferable that, subsequently, the film is introduced to a tenter while the both ends of the film being held by clips, and, in an atmosphere heated to a temperature of from 80° C. to 150° C., a transverse stretching is performed in a direction perpendicular to the length direction, that is, in the width direction, with a stretching stress of from 8 MPa to 20 MPa and a stretch ratio of from 3.4 times to 4.5 times, and more preferably with a stretching stress of from 10 MPa to 18 MPa and a stretch ratio of from 3.6 times to 4.2 times.

A stretched area ratio (longitudinal stretch ratioxtransverse stretch ratio) by the biaxial stretching is preferably from 9 times to 20 times. If the area ratio is from 9 times to 20 times, it is possible to obtain a biaxially oriented polyester film having a high degree of plane orientation, a thickness after stretching of from 100 μm to 350 μm, a degree of crystallinity of from 30% to 40%, and an equilibrium moisture content of from 0.1% by mass to 0.25% by mass.

A method of stretching biaxially may be either, as described in the above, a sequential biaxial stretching method that performs stretching in the length direction and the width direction separately or a simultaneous biaxial stretching method that performs stretching in the length direction and the width direction at the same time.

(3) Heat Setting Process

To provide planarity and dimension stability by completing the crystal orientation of the obtained biaxially stretched film, it is preferable to subsequently perform a heat setting treatment in the tenter. It is preferable to perform a heat setting treatment on the biaxially stretched film with a tensile strength of from 1 kg/m to 10 kg/m and a temperature of from 210° C. to 230° C. It is possible to improve planarity and dimension stability and control the difference between moisture contents measured arbitrarily at 10 cm intervals from 0.01% by mass to 0.06% by mass by performing a heat setting treatment under such a condition.

Preferably, a heat setting treatment is performed at a temperature of from the glass transition temperature (Tg) of a resin which is a raw material to less than a melting point (Tm) for from 1 second to 30 seconds, and then the resin is uniformly cooled, and further cooled down to room temperature. Generally, if a heat setting treatment temperature (Ts) is low, thermal contraction of a film is large, and therefore a high heat setting treatment temperature is preferable to provide a high thermal dimension stability. However, if a heat setting treatment temperature is too high, oriented crystallinity decreases, and therefore there are cases in which the moisture content of the formed film increases, and thus hydrolysis resistance deteriorates. Therefore, the heat setting treatment temperature (Ts) of the polyester film according to the present invention is preferably 40° C.≦(Tm−Ts)≦90° C., and more preferably 50° C.≦(Tm−Ts)≦80° C., and still more preferably 55° C.≦(Tm−Ts)≦75° C.

Furthermore, the polyester film according to the present invention can be used as a back sheet for constituting a solar cell module; however, since there are cases in which an atmosphere temperature increases to about 100° C. when using the module, the heat setting treatment temperature (Ts) is preferably from 160° C. to Tm-40° C. (under a condition of Tm-40° C.>160° C.), and more preferably from 170° C. to Tm-50° C. (under a condition of Tm-50° C.>170° C.), and still more preferably from 180° C. to Tm-55° C. (under a condition of Tm-55° C.>180° C.). The heat setting treatment is preferably carried out in two or more divided areas by sequentially lowering the temperature with a temperature difference in a range of from 1° C. to 100° C.

Optionally, a 1 to 12% relaxation treatment may be performed in the width direction or the length direction.

The heat-set polyester film is cooled down normally to Tg or lower and cut at both ends of the polyester film held by clips, and rolled into a roll shape. At this time, it is preferable to perform a 1 to 12% relaxation treatment in the width direction and/or the length direction in a temperature range of from Tg to the final heat setting treatment temperature.

From the viewpoints of dimension stability, it is preferable to perform cooling, from the final heat setting treatment temperature to room temperature, at a cooling rate of from 1° C./sec to 100° C./sec. Particularly, it is preferable to perform cooling from Tg+50° C. to Tg at a cooling rate of from 1° C./sec to 100° C./sec. The methods for cooling and relaxation are not particularly limited, and conventionally known methods can be used, but from the viewpoints of improvement in the dimension stability of the polyester film, it is particularly preferable to perform these treatments while sequentially cooling the film at multiple temperature areas.

When manufacturing the polyester film, for the purpose of improving the strength of the polyester film, known stretching used for stretched films, such as multi-step longitudinal stretching, re-longitudinal stretching, re-longitudinal and transverse stretching, and transverse-longitudinal stretching, may be performed. The order of a longitudinal stretching and a transverse stretching may be switched.

(Polyester Film for Sealing the Back Face of a Solar Cell)

The polyester film according to the present invention is excellent in terms of hydrolysis resistance and shape stability, thus being preferable as polyester film for sealing the back face of a solar cell.

(Protective Film for the Back Face of a Solar Cell)

It is possible to constitute a protective film for the back face of a solar cell by providing at least one layer of a functional layer, such as an easy adhesion layer, a UV absorbing layer, and a white layer, on the polyester film according to the present invention.

For example, the following functional layers may be provided by coating on the polyester film after the biaxial stretching. Known coating technologies, such as a roll coating method, a knife edge coating method, a gravure coating method, and a curtain coating method, can be used for the provision by coating.

Before the provision by coating, a surface treatment (for example, a flame treatment, a corona treatment, a plasma treatment, and an ultraviolet treatment) may be performed. Furthermore, it is preferable to attach layers using an adhesive.

—Easy Adhesion Layer—

The polyester film according to the present invention can have an easy adhesion layer provided as the outmost layer at one side thereof When the polyester film is attached to a cell main body including power generation devices, the easy adhesion layer is provided at the closest position to the power generation devices (the farthest position from the film) on the polyester film, and therefore the layer can improve adhesion, for example, between the polyester film according to the present invention (or a back sheet including the film) and a sealing material which is an object to be attached to the film (for example, an EVA resin that seals solar cell devices).

The material that composes the easy adhesion layer is not particularly limited as long as, for example, it can develop adhesion with a sealing material, such as an EVA resin that seals power generation devices. Preferable examples of such a material can include ethylene-vinyl acetate copolymer (EVA) and a mixture of EVA and one kind or two or more kinds of resins selected from a group consisting of ethylene-methyl acrylate copolymer (EMA), ethylene-ethyl acrylate copolymer (EEA), ethylene-butyl acrylate copolymer (EBA), ethylene-methacrylic acid copolymer (EMAA), an ionomer resin, a polyester resin, an urethane resin, an acryl resin, a polyethylene resin, a polypropylene resin, and a polyamide resin.

—Ultraviolet Absorbing Layer—

The ultraviolet (UV) absorbent may be provided by coating on the polyester film. It is preferable to use the UV absorbent after dissolving or dispersing it with, for example, an ionomer resin, a polyester resin, an urethane resin, an acryl resin, a polyethylene resin, a polypropylene resin, a polyamide resin, a vinyl acetate resin and a cellulose ester resin, and to control a transmittance of light with a wavelength of 400 nm or less to be 20% or less.

—White Layer—

In order that power generation efficiency is increased by scattering light that comes from incident sunlight and has passed through solar cell devices on the polyester film and reusing it at a solar cell, it is preferable to provide a white layer, on the polyester film, which acts as a light scattering layer. The white layer may be formed by attaching a resin layer (for example, a white PET) into which a white pigment (such as titania) has been kneaded or by co-extruding and overlapping. A white coating layer may be provided as described in JP-A No. 2007-306006 and JP-A No. 2006-73793.

In the conventional art, as a light scattering layer, a PET into which a white pigment is kneaded (a white PET) is laminated on a weather-resistant PET. Generally, titanium white (titanium oxide) is used as the white pigment, but titanium oxide has a photocatalyst function, thus accelerating hydrolysis of PET. Therefore, the white PET is likely to be decomposed (hydrolysis) over time, and acids (H⁺) generated therefrom diffuse to the attached weather-resistant PET, which also accelerates decomposition of the weather-resistant PET. With respect to such a problem, in the present invention, a strong scattering effect can be obtained by providing the white pigment by coating separately from the PET, thereby further improving weather resistance. Furthermore, to efficiently scatter light in the white layer including the white pigment, it is necessary to disperse the white pigment at a high concentration of 10% by mass or more. However, if the amount of a binder used is excessive, adhesion force easily decreases. With respect to this point, the polyester having surface characteristics such as in the present invention can easily secure adhesion force.

The thickness of the white layer is preferably from 1 μm to 10 μm, and more preferably from 2 μm to 8 μm, and still more preferably from 3 μm to 7 μm. If the thickness of the white layer is 1 μm or more, the light scattering property is strong, and power generation efficiency can be maintained at a high level when used for a solar cell. Meanwhile, if the thickness of the white layer is 10 μm or less, it is possible to maintain the adhesion force to an object to be attached at a high level.

—Fluorine Resin Layer·Si Resin Layer—

On the polyester film according to the present invention, it is preferable to provide at least one of a fluorine resin layer and a Si resin layer. By providing a fluorine resin layer and a Si resin layer, effects can be made to prevent contamination of the surface of the polyester film and to improve weather resistance. Specifically, it is preferable to have a fluorine resin coating layer described in the specifications of JP-A No. 2007-35694, JP-A No. 2008-28294, and WO 2007/063698.

It is also preferable to attach a fluorine-resin film, such as TEDLAR (trade name, manufactured by DuPont).

The thickness of the fluorine resin layer and the Si resin layer is each preferably in a range of from 1 μm to 50 μm, and more preferably in a range of from 3 μm to 40 μm.

—Inorganic Layer—

The polyester film according to the present invention is also preferably provided with an inorganic layer. By providing an inorganic layer, the inorganic layer can be made to act as a damp proofing layer or a gas barrier layer that prevents intrusion of water or gas into the polyester. The moisture vapor permeating amount (moisture permeability) of the inorganic layer is preferably from 10⁰ g/m²·d to 10⁻⁶ g/m²·d, and more preferably from 10¹ g/m²·d to 10⁻⁵g/m²·d, and still more preferably from 10² g/m²·d to 10⁻⁴ g/m²·d.

The following dry method can be preferably used for this.

Examples of the method that forms the gas barrier layer by the dry method can include a vacuum vapor deposition method, such as resistance heating vapor deposition, electron-beam vapor deposition, induction heating vapor deposition, and an assist method by plasma or an ion beam therefor; a sputtering method, such as a reactive sputtering method, an ion beam sputtering method, and an electron cyclotron (ECR) sputtering method; a physical vapor deposition method (PVD method), such as an ion-plating method; and a chemical vapor deposition method (CVD method) using, for example, heat, light, or plasma. Among the above, the vacuum vapor deposition method that forms a film by a vapor deposition method under vacuum is preferable.

Here, in a case in which a material that forms the gas barrier layer has, for example, an inorganic oxide, an inorganic nitride, an inorganic oxynitride, an inorganic halide, or an inorganic sulfide as the main component, it is also possible to directly volatize a material having a composition substantially similar to the composition of the gas barrier layer to be formed and deposit it on a base material; however, in the case of using this method, the composition varies during the volatilization, and, consequently, there are cases in which a formed film does not have uniform characteristics. Therefore, examples of the method can include 1) a method that uses a material having a composition substantially similar to the composition of the barrier layer to be formed as a volatilization source and volatizes it while for assistance introducing an oxygen gas in the case of an inorganic oxide, a nitrogen gas in the case of an inorganic nitride, a mixed gas of an oxygen gas and a nitrogen gas in the case of an inorganic oxynitrde, a halogen-based gas in the case of an inorganic halide, and a sulfur-based gas in the case of an inorganic sulfide, respectively, into the system, 2) a method that uses an inorganic substance group as a volatilization source and, while volatizing the inorganic substance group, introduces an oxygen gas in the case of an inorganic oxide, a nitrogen gas in the case of an inorganic nitride, a mixed gas of an oxygen gas and a nitrogen gas in the case of an inorganic oxynitrde, a halogen-based gas in the case of an inorganic halide, and a sulfur-based gas in the case of an inorganic sulfide, respectively, into the system, and deposits it on the surface of a base material while making the inorganic substance and the introduced gas react, and 3) a method that uses an inorganic substance group as a volatilization source, and volatizes it so as to form an inorganic substance layer, and then make the inorganic substance layer and the introduced gas react by retaining the formed layer under an oxygen gas atmosphere in the case of an inorganic oxide, a nitrogen gas atmosphere in the case of an inorganic nitride, a mixed gas of an oxygen gas and a nitrogen gas atmosphere in the case of an inorganic oxynitrde, a halogen-based gas atmosphere in the case of an inorganic halide, and a sulfur-based gas atmosphere in the case of an inorganic sulfide.

Among the above, from the standpoints of easy volatilization from the volatilization source, the methods 2) and 3) are preferably used. Furthermore, from the standpoints of easy control of film qualities, the method 2) is more preferably used. In a case in which the barrier layer is an inorganic oxide, a method that uses an inorganic substance group as the volatilization source and volatizes it so as to form a layer of the inorganic substance group, and then leaves it under air so as to naturally oxidize the inorganic substance group is also preferable from the standpoints of easy formation.

It is also preferable to attach an aluminum foil and use it as the barrier layer. The thickness is preferably from 1 μm to 30 μm. If the thickness is 1 μm or more, it becomes difficult for water to intrude into the polyester film over time (thermally), therefore hydrolysis is not likely to occur, and if the thickness is 30 μm or less, the thickness of the barrier layer does not become too thick so that deformation is not generated on the film due to stress in the barrier layer.

(Solar Cell Module)

The solar cell module according to the present invention includes the above-mentioned polyester film (which may be a back sheet) according to the present invention, and preferably further includes, for example, a transparent substrate at the side on which sunlight is incident, a solar cell device that converts light energy of sunlight to electrical energy, and a sealing material that seals solar cell devices.

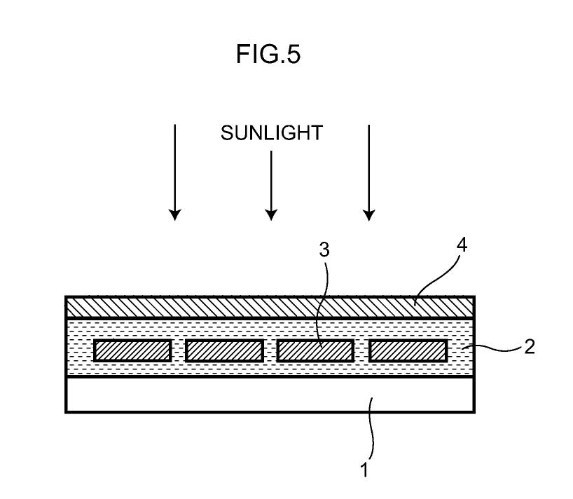

The solar cell module, for example, as shown in FIG. 5, may have a configuration that seals power generation devices (solar cell devices) 3 connected to metal wires (not shown) for electrical output by a sealing material 2, such as ethylene vinyl acetate copolymer (EVA) resin, and sandwiches this between a transparent substrate 4, such as glass, and a back sheet 1 including the polyester film according to the present invention so as to attach them to each other.

The transparent substrate preferably has a light permeability so that sunlight can permeate, and can be properly selected from base materials that enable light permeation. From the viewpoints of power generation efficiency, a substrate having a higher light permeability is more preferable, and examples of such a substrate can include a glass substrate and a transparent resin, such as an acryl resin.

As the solar cell devices, a variety of known solar cell devices, such as a silicon-based device, such as single crystal silicon, polycrystalline silicon, and amorphous silicon; and a III-V group or II-VI group compound semiconductor, such as copper-indium-gallium-selenium, copper-indium-selenium, cadmium-tellurium, and gallium-arsenic may be appropriately applied.

According to an aspect of the invention, there are provided the following embodiments <1> to <13>.

<1> A biaxially oriented polyester film having:

an equilibrium moisture content of from 0.1% by mass to 0.25% by mass;

a difference between moisture contents measured at 10 cm intervals of from 0.01% by mass to 0.06% by mass;

a degree of crystallinity of from 30% to 40%;

a concentration of terminal carboxyl groups of from 5 equivalents/ton to 25 equivalents/ton; and

a thickness of from 100 μm to 350 μm.

<2> The polyester film according to <1>, having a thickness of from 255 μm to 350 μm.

<3> The polyester film according to <1> or <2>, having an intrinsic viscosity of from 0.6 to 1.3.

<4> The polyester film according to any one of <1> to<3>, wherein an increase in the concentration of terminal carboxyl groups after performing an 80-hour long thermal treatment under an environment of 120° C. and 100% RH is from 30 equivalents/ton to 65 equivalents/ton.

<5> A manufacturing method of a polyester film, comprising: cooling a molten film-shaped polyester extruded from an extrusion die at a rate of from 250° C./min to 800° C./min; and

performing a longitudinal stretching in a length direction with a stretching stress of from 5 MPa to 15 MPa and a stretch ratio of from 2.5 times to 4.5 times, and a transverse stretching in a width direction, on the cooled film-shaped polyester, so that a thickness of the polyester film after the longitudinal stretching and the transverse stretching becomes from 100 μm to 350 μm.

<6> The manufacturing method of a polyester film according to <5>, wherein the thickness of the polyester film after the longitudinal stretching and the transverse stretching becomes from 255 μm to 350 μm.

<7> The manufacturing method of a polyester film according to <5> or <6>, wherein the molten film-shaped polyester is cooled by a cast roll.

<8> The manufacturing method of a polyester film according to any one of <5> to <7>, wherein the transverse stretching is performed with a stretching stress of from 8 MPa to 20 MPa and a stretch ratio of from 3.4 times to 4.5 times.

<9> The manufacturing method of a polyester film according to any one of <5> to <8>, further comprising, after the longitudinal stretching and the transverse stretching, performing a heat setting treatment on the polyester film with a tensile strength of from 1 kg/m to 10 kg/m and at a temperature of from 210° C. to 230° C.

<10> The manufacturing method of a polyester film according to any one of <5> to <9>, wherein solid-phase polymerized pellets are used as a polyester to be extruded from the extrusion die.

<11> A polyester film for sealing a back face of a solar cell, which is a polyester film manufactured by the manufacturing method according to any one of <5> to <10>.

<12> A protective film for a back face of a solar cell, comprising the polyester film according to any one of <1> to <4> and <11>.

<13> A solar cell module comprising the polyester film according to any one of <1> to <4> and <11>.

Therefore, according to the present invention, it is possible to provide a polyester film, a manufacturing method thereof, a polyester film for sealing the back face of a solar cell, a protective film for the back face of a solar cell, and a solar cell module, which are excellent in terms of hydrolysis resistance and dimension stability, and suitable for long term use under an extreme environment, such as a use for a solar cell.

### EXAMPLES

Hereinafter, the present invention will be described in detail with examples, but the present invention is not limited to the examples below. Meanwhile, unless otherwise described, “parts” refers to parts by mass.

### Example 1

### —Synthesis of a Polyester Resin—

(1) PET-1: PET Produced Using Ti Catalyst

As shown below, a polyester resin was obtained by a continuous polymerization apparatus using a direct esterification method that makes terephthalic acid and ethylene glycol directly react and removes water by distillation for carrying out esterification, and then performs condensation polymerization under reduced pressure after esterification.

(1) Esterification Reaction

4.7 ton of high-purity terephthalic acid and 1.8 ton of ethylene glycol were mixed for 90 minutes in a first esterification reaction tank so as to form a slurry, whereby the slurry was continuously supplied to the first esterification reaction tank in a flow rate of 3800 kg/h. Further, an ethylene glycol solution of a citric acid chelate titanium complex (VERTEC AC-420, trade name, manufactured by Johnson Matthey) in which citric acids coordinate a Ti metal was continuously supplied, and a reaction was performed with the inside temperature of the reaction tank at 250° C. for an average retention time of about 4.3 hours under stirring. At this time, the citric acid chelate titanium complex was continuously added so that the amount of Ti element added became 9 ppm. At this time, the acid value of the obtained oligomer was 600 equivalents/ton.

This reaction product was transferred to a second esterification reaction tank, and reacted under an inside temperature of the reaction tank at 250° C. for an average retention time of about 1.2 hours under stirring so as to obtain an oligomer with an acid value of 200 equivalents/ton. The inside of the second esterification reaction tank was divided into three zones, and an ethylene glycol solution of magnesium acetate was continuously supplied in a second zone so that the amount of Mg element added became 75 ppm, and then an ethylene glycol solution of trimethyl phosphate was continuously supplied in a third zone so that the amount of P element added became 65 ppm.

(2) Condensation Polymerization Reaction

A product of the esterification reaction obtained in the above was continuously supplied to a first condensation polymerization reaction tank, and polycondensed under conditions of a reaction temperature of 270° C., an inside pressure of the reaction tank at 20 torr (2.67×10⁻³ MPa), and an average retention time of about 1.8 hours under stirring.

Furthermore, the product was transferred to a second condensation polymerization reaction tank, and reacted (polycondensed) under conditions of a temperature inside the reaction tank of 276° C., an inside pressure of the reaction tank at 5 torr (6.67×10⁻⁴ MPa), and an average retention time of about 1.2 hours under stirring.

Next, the product was transferred to a third condensation polymerization reaction tank, and reacted (polycondensed) under conditions of a temperature inside the reaction tank of 278° C., an inside pressure of the reaction tank at 1.5 torr (2.0×10⁻⁴ MPa), and an average retention time of 1.5 hours so as to obtain a reaction product (polyethylene terephthalate (PET)).

Next, the obtained reaction product was ejected into cold water in a strand shape and immediately cut so as to manufacture pellets of a polyester resin <cross section: long diameter of about 4 mm and a short diameter of about 2 mm, length: about 3 mm>. It is possible to dry these pellets at 180° C. under a vacuum, and then feed them into the raw material hopper of a uniaxial kneading extruder including a screw in the cylinder, and form a film by extruding.

As a result of measuring the obtained polyester resin as follows using a high resolution high frequency inductively coupled plasma mass spectrometer (HR-ICP-MS; trade name, AttoM, manufactured by SII Nano Technology Inc.), the polyester resin exhibited Ti=9 ppm, Mg=75 ppm, and P=60 ppm. P slightly decreased with respect to the original amount added, but it is assumed that it was volatized during the polymerization step.

The obtained polymer exhibited an IV=0.65, a concentration of terminal carboxyl groups (AV)=22 equivalents/ton, a melting point=257° C., and a solution haze=0.3%.

(2) PET-2: PET Produced Using Ti Catalyst

A slurry of 100 kg of a high-purity terephthalic acid (manufactured by Mitsui Chemicals Inc.) and 45 kg of ethylene glycol (manufactured by Nippon Shokubai Co., Ltd.) was sequentially supplied for 4 hours to the esterification reaction tank maintained at a temperature of 250° C. and a pressure of 1.2×10⁵ Pa with about 123 kg bis(hydroxyethyl)terephthalate previously included, and, even after the completion of supply, esterification reaction was further performed for 1 hour. Then, 123 kg of the obtained product of the esterification reaction was transferred to the condensation polymerization tank.

Subsequently, ethylene glycol was added to the condensation polymerization reaction tank to which the product of the esterification reaction had been transferred in an amount of as much as 0.3% by mass with respect to the obtained polymer. After stirring for 5 minutes, ethylene glycol solutions of cobalt acetate and manganese acetate were added in an amount of as much as 30 ppm and 15 ppm of the metal elements, respectively, with respect to the obtained polymer. After stirring for another 5 minutes, 2% by mass ethylene glycol solution of a titanium alkoxide compound was added so that the amount of Ti element became 5 ppm with respect to the obtained polymer. After 5 minutes, 10% by mass ethylene glycol solution of diethyl phosphono ethyl acetate was added so that the amount of P element became 5 ppm with respect to the obtained polymer. Then, while stirring an oligomer at 30 rpm, the temperature of the reaction system was slowly increased from 250° C. to 285° C. and the pressure was decreased down to 40 Pa. The necessary times to reach the final temperature and the final pressure were both 60 minutes. The reaction system was nitrogen-purged at a point of time when a predetermined stirring torque was reached, and returned to normal pressure, and then the condensation polymerization reaction was stopped. The obtained reaction product was ejected into cold water in a strand shape and immediately cut so as to manufacture pellets of a polymer (diameter: about 3 mm, length: about 7 mm). Meanwhile, a time span from when the pressure began to decrease to when a predetermined stirring torque was reached was 3 hours.

The obtained polymer exhibited an IV=0.65, a concentration of terminal carboxyl groups (AV)=25 equivalents/ton, a melting point=259° C., and a solution haze=0.7%. The content of Ti element of a titanium catalyst-derived titanium compound measured from the polymer was 5 ppm, and the content of P element of a phosphorous compound was 5 ppm, and therefore Ti/P=1. It was observed that the content of an antimony compound and the content of a germanium compound were below the lower limit of detection, that is, substantially 0 ppm.

A synthesis method for a titanium alkoxide compound used as a catalyst for the above polymerization will be shown in the below.

Ethylene glycol (496 g, 8.00 mol) were added from a dropping funnel to titanium tetraisopropoxide (285 g, 1.00 mol) being stirred in a 2L flask with a stirrer, a condenser, and a thermometer. An addition rate was adjusted so that reaction heat heated a substance in the flask to about 50° C. A 32% by mass aqueous solution of NaOH (125 g, 1.00 mol) was slowly added to the reaction flask from a dropping funnel and reacted so as to generate a transparent yellowish liquid of a titanium alkoxide compound (Ti content: 4.44% by mass).

(3) PET-3: Sb, Ti Catalyst

According to the method shown in the below, PET samples including an amount of antimony (Sb) and a different amount of titanium (Ti) were obtained by performing polymerization by adding different amounts of Ti catalyst (a titanium alkoxide compound). The specific method is as follows.

After 100 parts of dimethyl terephthalate and 70 parts of ethylene glycol were ester-exchanging reacted according to a routine method using calcium acetate monohydrate and magnesium acetate tetrahydrate as ester exchanging catalysts, trimethyl phosphate was added, and then the ester exchanging reaction was substantially finished. Furthermore, titanium tetrabutoxide and antimony trioxide were added. Then, condensation polymerization was performed according to a routine method under a high temperature and high vacuum so as to obtain polyethylene terephthalate with an intrinsic viscosity (IV)=0.60 and a concentration of terminal carboxyl groups (AV)=27 equivalents/ton.

(4) PEN Resin

Ester exchange reaction was performed with a mixture of 100 parts of dimethyl 2,6-naphthalate and 60 parts of ethylene glycol, and 0.030 parts of manganese acetate tetrahydrate in an esterification reaction container while slowly increasing the temperature from 140° C. to 230° C. and distilling methanol generated outside the system. The reaction continued at 190° C., and, after the methanol was completely distilled, 0.020 parts of trimethyl phosphate were added as a phosphorous compound so as to finish the reaction. Subsequently, after 5 minutes, 0.024 parts of antimony trioxide which is a polymerization catalyst were added, and heated to 250° C. so as to distill some of ethylene glycol, and then an oligomer was transferred to a condensation polymerization reaction container. Then, while heating according to a routine method under a high vacuum, the reaction was made to stop at a point of time when a desired viscosity was reached at a final temperature of 295° C., and the reaction product was continuously extruded from the discharging portion into a strand shape and cooled and cut so as to obtain granular pellets of polyethylene-2,6-naphthalate with a length of about 3 mm. The polymer exhibited an intrinsic viscosity (IV)=0.60 and a concentration of terminal carboxyl groups (AV)=23 equivalents/ton.

—Solid-Phase Polymerization—

The PET samples polymerized in the above were pelletized (diameter 3 mm, length 7 mm), and a part of the obtained resin pellets was solid-phase polymerized by a batch method or a continuous method.

(i) Batch Method

After the PET-1 resin pellets synthesized in the above were fed into a vessel, they were vacuumed and solid-phase polymerized under the following conditions while being stirred.

After performing pre-crystallization treatment at 150° C., a solid-phase polymerization reaction was performed at 190° C. for 30 hours.

The obtained polyester resin (solid-phase polymerized PET 1) exhibited an intrinsic viscosity (IV)=0.78 and a concentration of terminal carboxyl groups (AV)=15 equivalents/ton.

(ii) Continuous Method

The obtained PET-1 resin pellets were fed into a silo with a length/diameter=20, and pre-crystallized at 150° C., and then the speed of a delivery machine provided at the outlet was adjusted so that the resin was retained therein until 40 hours had passed. At this time, a heated N₂ air stream was blown while heating the surrounding of the silo to be a temperature of 200° C. The obtained polyester resin (solid-phase polymerized PET 2) exhibited an intrinsic viscosity (IV)=0.86 and a concentration of terminal carboxyl groups (AV)=12 equivalents/ton.

—Extrusion Molding—

The PET samples (solid-phase polymerized PET1) solid-phase polymerized in the above manner were dried so as to have a moisture content of 20 ppm or less, and fed into the hopper of a uniaxial kneading extruder with a diameter of 50mm, and melted at the temperatures described in Table 1 below, and extruded. After passing these molten bodies (melt) through a gear pump and a filter (with a pore diameter of 20 μm), the samples were extruded from the die to a cooling (chill) cast drum in the following conditions. Meanwhile, the extruded melts were attached to the cooling cast drum using an electrostatic application method.

<Conditions>

(a) Thickness of the Melt Extruded from the Die

The ejection amount of the extruder and the slit height of the die were adjusted. Thereby, an adjustment was made to obtain the thickness of unstretched film in Table 1 below. Meanwhile, the thickness of unstretched film was measured by an automatic thickness meter installed at the outlet of the cast drum.

(e) Cooling Rate of the Melts

The temperature of the cooling cast drum, and the temperature and air volume of a cold wind blown out from an auxiliary cooling apparatus installed opposite to the cooling cast drum were adjusted, and cooling rates in Table 1 below were achieved by applying it to a melt film-shaped resin so as to accelerate cooling. The cooling rate was obtained from the temperature of landing point of the extruded melt film-shaped resin on the cast drum and the temperature of peeling point from the cast drum.

(f) Temperature Variation in Cooling Roll

Using hollow chilled roll (cooling cast drum), temperature was adjusted by flowing a coolant (for example, water) in the hollow chilled roll. At this time, a baffle plate was installed in the chill roll and temperature variation was generated. Temperature variation was adjusted by the baffle plate while measuring the temperature of the surface of the chill roll by a non-contact type thermometer (thermo viewer).

—Stretching—

Sequential biaxial stretching was performed with the following method on unstretched film extruded and solidified on the cooling roll in the above manner, thereby obtaining film with the thickness described in Table 2 below.

<Stretching Method>

(a) Longitudinal Stretching

Unstretched film was passed through two pairs of nip rolls having different circumferential velocities and thus stretched in a length direction (transportation direction). Meanwhile, the longitudinal stretching was performed by setting the preheating temperature to 80° C. and setting the longitudinal stretching temperature, longitudinal stretching stress, and longitudinal stretch ratio to the conditions in Table 1 below, respectively.

(b) Transverse Stretching

The longitudinally-stretched film was stretched transversely using a tenter with the transverse stretching temperature, transverse stretching stress, and transverse stretch ratio set to the conditions shown in Table 1, respectively.

—Heat Setting·Thermal Relaxation—

Subsequently, the stretched film for which the longitudinal and transverse stretching had been completed was heat-set at the conditions shown in Table 1 below (heat setting time: 10 seconds). Furthermore, after heat setting, the film was thermally relaxed under the following conditions by contracting the width of the tenter (thermal relaxation temperature: 200° C.).

—Winding—

After heat setting and heat relaxation, 20 cm of the film was trimmed at each of both ends. Then, a pressing process (knurling) was performed with the width of 10 mm at the both ends, and then the film was wound with a tensile strength of 25 kg/m. Meanwhile, film manufacturing width was 2.5 m and roll length was 2000 m.

In the above manner, PET films for the present invention and comparison (hereinafter, together referred to as “sample films”) were manufactured.

—Evaluation of the Films—

With respect to the sample films manufactured in the above manner, the thickness, thickness variation, AV, IV, degree of crystallinity, equilibrium moisture content, difference between moisture contents (at 10 cm intervals), and increase in AV before and after a thermal treatment (80 hr.) were measured, and the elongation at rupture and retention rate of rupture strength before and after a thermal treatment (80 hr.) were measured, and then hydrolysis resistance and dimension stability were evaluated. The respective results of the measurement and the evaluation are shown in Table 2 below.

Meanwhile, the measurement and evaluation of the respective properties were performed in the following manner.

(Thickness)

The thickness of the polyester film was measured using a contact type film thickness meter (manufactured by Anritsu Corporation) by selecting 50 sample points at equal intervals across 0.5 m along the length direction and appointing 50 sample points at equal intervals (50 equally divided points in the width direction) across the entire width of the manufactured film along the width direction, and measuring the thickness at these 100 points. The average thickness of these 100 points was obtained and then considered as an average thickness of the film.

(Thickness Variation)

The thickness variation of the polyester film was obtained using the formula below by obtaining the maximum thickness, minimum thickness, and average thickness of the above 100 points.

Thickness variation (%)=100×(maximum thickness−minimum thickness)/average thickness

(Degree of Crystallinity)

The degree of crystallinity of the film was obtained by the formula below in which a density of completely amorphous polyester dA=1.335, a density of completely crystalline polyester dC=1.501, and a density of the sample is represented by d.

Degree of crystallinity (%)={(d−dA)/(dC−dA)}×100

(Equilibrium Moisture Content)

The equilibrium moisture content of the film was obtained in the following manner. A total of 20 samples were taken arbitrarily from 10 points at 10 cm intervals along the length direction of the film and 10 points at 10 cm intervals along the width direction of the film, respectively, and the moisture content of each of the samples was measured in the following manner.

The humidity of the polyester film was adjusted at 25° C., 60% RH for 3 days, and then measured at 200° C. using a trace moisture analyzer (Karl Fisher method). The average value of the moisture contents of the 20 samples was considered as the equilibrium moisture content of the film.

(Difference Between Moisture Contents)

The difference between the largest value and the smallest value in the moisture content values of the 20 samples was considered as the difference between moisture contents.

(AV: Concentration of Terminal Carboxyl Groups)

The amount of terminal carboxyl groups was measured using a neutralization titration method. That is, polyester was dissolved in benzyl alcohol, phenol red indicator was added, and titrated with a water/methanol/benzyl alcohol solution of sodium hydroxide.

(IV: Intrinsic Viscosity)

The intrinsic viscosity (IV) refers to a value obtained by extrapolating a concentration to zero in a value obtained by dividing a specific viscosity (ηₛₚ=ηᵣ=1 ) obtained by subtracting one from the ratio ηᵣ between solution viscosity (η) and solvent viscosity (η₀) (=η/η₀; relative viscosity) by a concentration. The IV can be obtained from the viscosity of a solution of 25° C. obtained by dissolving a polyester resin in a mixed solvent of 1,1,2,2-tetrachloroethane/phenol (=2/3 [mass ratio]) using an Ubbelohde type viscometer.

(Hydrolysis Resistance)

The hydrolysis resistance was evaluated from a measured value which was obtained by measuring elongation at rupture of the biaxially stretched polyester film before and after a thermal treatment for 80 hours in an atmosphere (120° C., 100% RH) in the following manner.

The biaxially stretched polyester film was cut into 10 pieces with a size of 1 cm width×20 cm in each of MD (film manufacturing flowing direction) and TD (film width direction). Using a TENSILON universal tensile testing machine (RTC-1210, manufactured by Orientec Corp.), the film was pulled at 20%/min with 10 cm between chucks under an environment of 25° C., 60% RH, and the elongation at rupture and rupture strength was obtained. Also, average values of the elongation at rupture and rupture strength of the respective 10 pieces of MD and TD were obtained respectively, and the retention rate of the elongation at rupture and the retention rate of the rupture strength of MD and TD were calculated from the formulae below, and considered as an index to evaluate hydrolysis resistance.

Retention rate of the elongation at rupture (%)=(elongation at rupture after 80-hour long thermal treatment/elongation at rupture before the thermal treatment)×100

Retention rate of the rupture strength (%)=(rupture strength after 80-hour long thermal treatment/rupture strength before the thermal treatment)×100

The evaluation relating to hydrolysis resistance in Table 2 is as follows.

A: Both the retention rate of the elongation at rupture and the retention rate of the rupture strength in the MD and TD directions are 70% or more.

B: Both the retention rate of the elongation at rupture and the retention rate of the rupture strength in the MD and TD directions are from 50% to less than 70%.

C: Both the retention rate of the elongation at rupture and the retention rate of the rupture strength in the MD and TD directions are from 30% to less than 50%.

D: Both the retention rate of the elongation at rupture and the retention rate of the rupture strength in the MD and TD directions are less than 30%.

(Dimension Stability)

The biaxially stretched polyester film was cut into 10 pieces with a size of 5 cm width×15 cm in each of MD direction (film manufacturing flowing direction) and TD direction (film width direction), respectively. After the humidity of the polyester film was adjusted at 25° C., 60% RH for 24 hours, the length was measured using pin gauges (an average length of each of MD and TD is represented by L1). Then, these samples were thermally treated at 150° C. for 30 minutes, and, again, the humidity was adjusted at 25° C., 60% RH for 24 hours, and then the length was measured using pin gauges (an average length of each of MD and TD is represented by L2). Based on the formula below, the dimensional variation rate was obtained.

Dimensional variation rate (%)={100×(L1−L2)/L1}

The evaluation relating to dimension stability in Table 2 is as follows.

A: Both the dimensional variation rates in the MD and TD directions are less than 1.0%.

B: Both the dimensional variation rates in the MD and TD directions are from 1.0% to less than 1.6%.

C: Both the dimensional variation rates in the MD and TD directions are from 1.6% to less than 2.2%.

D: Both the dimensional variation rates in the MD and TD directions are 2.2% or more.

—8. Manufacturing of a Back Sheet—

On one surface of each sample film obtained in the above manner, the following (i) reflection layer and (ii) easy adhesion layer were provided in this order by coating.

(i) Reflection Layer (Colored Layer)

Firstly, in the beginning, components of the following composition were mixed and dispersed for 1 hour by a DYNO-Mill type dispenser so as to prepare a pigment dispersion.

<Prescription of a Pigment Dispersion>

| | |
|---|---|
| Titanium dioxide | 39.9% by mass |
| (TIPAQUIE R-780-2, manufactured by Ishihara Sangyo | |
| Kaisha Ltd., solid content 100%) | |
| Polyvinyl alcohol | 8.0% by mass |
| (PVA-105, manufactured by Kuraray Co., Ltd., | |
| solid content 10%) | |
| Surfactant (DEMOL EP, manufactured by Kao | 0.5% by mass |
| Corporation, solid content 25%) | |
| Distilled water | 51.6% by mass |

Next, a coating liquid for forming a reflection layer was prepared by mixing components of the following composition using the obtained pigment dispersion.

<Prescription of a Coating Liquid for Forming the Reflection Layer>

| | |
|---|---|
| The above pigment dispersion | 71.4 parts by mass |
| Aqueous polyacrylic resin dispersion | 17.1 parts by mass |
| (Binder: JURYMER ET410, manufactured by Nihon | |
| Junyaku Co., Ltd., solid content: 30% by mass) | |
| Polyoxyalkylene alkyl ether | 2.7 parts by mass |
| (NAROACTY CL95, manufactured by Sanyo | |
| Chemical Industries Ltd., solid content: | |
| 1% by mass) | |
| Oxazoline compound | 1.8 parts by mass |
| (EPOCROSS WS-700, manufactured by Nippon | |
| Shokubai Co., Ltd., solid content: 25% by mass; | |
| crosslinking agent) | |
| Distilled water | 7.0 parts by mass |

The coating liquid for forming a reflection layer obtained in the above manner was applied on the sample film, and dried at 180° C. for 1 minute so as to form a reflection layer (dried thickness=5 μm; white layer) with an amount of applied titanium dioxide of 6.5 g/m².

(ii) Easy Adhesion Layer

Components of the following composition were mixed so as to prepare a coating liquid for an easy adhesion layer, and the liquid was applied on the reflection layer so that the amount of the binder applied became 0.09 g/m². Then, the liquid was dried at 180° C. for 1 minute so as to form an easy adhesion layer with a dried thickness of 1 μm.

<Composition of a Coating Liquid for the Easy Adhesion Layer>

| | |
|---|---|
| Aqueous polyolefin resin dispersion | 5.2% by mass |
| (Binder: CHEMIPEARL S75N, manufactured by | |
| Mitsui Chemicals Inc., solid content: 24%) | |
| Polyoxyalkylene alkyl ether | 7.8% by mass |
| (NAROACTY CL95, manufactured by Sanyo | |
| Chemical Industries Ltd., solid content: | |
| 1% by mass) | |
| Oxazoline compound | 0.8% by mass |
| (EPOCROSS WS-700, manufactured by Nippon | |
| Shokubai Co., Ltd., solid content: 25% by mass) | |
| Aqueous silica fine particle dispersion | 2.9% by mass |
| (AEROSIL OX-50, manufactured by Nippon | |
| Aerosil Co., Ltd., solid content: 10% by mass) | |
| Distilled water | 83.3% by mass |

Next, on the surface of the sample film opposite to the surface on which the reflection layer and the easy adhesion layer had been formed, the following (iii) an undercoating layer, (iv) barrier layer, and (v) antifouling layer were provided by coating sequentially from the side of the sample film.

(iii) Undercoating Layer

Components of the following composition were mixed so as to prepare a coating liquid for an undercoating layer, and the coating liquid was applied to the sample film, and dried at 180° C. for 1 minute so as to form the undercoating layer (dried coating amount: about 0.1 g/m²).

<Composition of a Coating Liquid for the Undercoating Layer>

| | |
|---|---|
| Polyester resin | 1.7% by mass |
| (BIRONAL MD-1200, manufactured by Toyobo Co., | |
| Ltd., solid content: 17% by mass) | |
| Polyester resin | 3.8% by mass |
| (PESRESIN A-520, manufactured by Takamatsu Oil | |
| & Fat, Co., Ltd., solid content: 30%) | |
| Polyoxyalkylene alkyl ether | 1.5% by mass |
| (NAROACTY CL95, manufactured by Sanyo | |
| Chemical Industries, solid content: | |
| 1% by mass) | |
| Carbodiimide compound | 1.3% by mass |
| (CARBODILITE V-02-L-2, manufactured by | |
| Nisshinbo Industries Ltd., solid content: | |
| 10% by mass) | |
| Distilled water | 91.7% by mass |

(iv) Barrier Layer

Subsequently, on the surface of the undercoating layer formed, a vapor deposited film of silicon oxide with a thickness of 800 Å was formed under the vapor deposition conditions below, and considered as the barrier layer.

### <Vapor Deposition Conditions>

Reaction gas mixing ratio (unit: slm): hexamethyl disiloxane/oxygen gas/helium=1/10/10
Degree of vacuum in a vacuum chamber: 5.0×10⁻⁶ mbar
Degree of vacuum in a vapor deposition chamber: 6.0×10⁻² mbar
Power supply for a cooling·electrode drum: 20 kW
Film transporting speed: 80 m/min

(v) Antifouling Layer

As shown in the below, coating liquids were prepared to form first and second antifouling layers, and the coating liquid for the first antifouling layer and the coating liquid for the second antifouling layer were applied on the barrier layer in this order to provide a two-layer structure of antifouling layers by coating.

<First Antifouling Layer>

—Preparation of a Coating Liquid for the First Antifouling Layer—

The components of the following composition were mixed to prepare a coating liquid for the first antifouling layer.

### <Composition of the Coating Liquid>

| | |
|---|---|
| CERANATE WSA1070 (manufactured by DIC Corporation) | 45.9 parts |
| Oxazoline compound (crosslinking agent) | 7.7 parts |
| (EPOCROSS WS-700, manufactured by Nippon Shokubai | |
| Co., Ltd., solid content: 25% by mass) | |
| Polyoxyalkylene alkyl ether | 2.0 parts |
| (NAROACTY CL95, manufactured by Sanyo Chemical | |
| Industries Ltd., solid content: 1% by mass) | |
| Pigment dispersion used for the reflection layer | 33.0 parts |
| Distilled water | 11.4 parts |

—Formation of the First Antifouling Layer—

The obtained coating liquid was applied onto the barrier layer so that an amount of the binder applied became 3.0 g/m², and dried at 180° C. for 1 minute so as to form the first antifouling layer.

—Preparation of a Coating Liquid for the Second Antifouling Layer—

The components of the following composition were mixed to prepare a coating liquid for the second antifouling layer.

<Composition of the Coating Liquid>

| | |
|---|---|
| Fluorine binder: OBBLIGATO (manufactured by | 45.9 parts by mass |
| AGC Coat-Tech Co., Ltd.) | |
| Oxazoline compound | 7.7 parts by mass |
| (EPOCROSS WS-700, manufactured by Nippon | |
| Shokubai Co., Ltd., solid content: 25% by mass; | |
| crosslinking agent) | |
| Polyoxyalkylene alkyl ether | 2.0 parts by mass |
| (NAROACTY CL95, manufactured by Sanyo | |
| Chemical Industries Ltd., solid content: | |
| 1% by mass) | |
| Pigment dispersion prepared for the reflection layer | 33.0 parts by mass |
| Distilled water | 11.4 parts by mass |

—Formation of the Second Antifouling Layer—

The prepared coating liquid for the second antifouling layer was applied onto the first antifouling layer formed on the barrier layer so that an amount of the binder applied became 2.0 g/m², and dried at 180° C. for 1 minute so as to form the second antifouling layer.

In the above manner, a back sheet having the reflection layer and the easy adhesion layer on one side of the polyester film and the undercoating layer, the barrier layer, and the antifouling layer on the other side was manufactured.

—Evaluation of the Back Sheet—

After performing a thermal treatment (120° C., 100% RH, 80 hours) on the back sheet on which the above (i) to (v) layers had been provided, evaluation was performed in a manner substantially similar to the above. It was observed that, compared with the back sheets using the polyester film manufactured as the comparative examples, the back sheets that used the polyester film manufactured according to the present invention had satisfactory hydrolysis resistance and dimension stability.

—Manufacturing of a Solar Cell—

Using each of the back sheets manufactured in the above manner, a solar cell module was manufactured by attaching with transparent filler to provide the structure shown in FIG. 1 of JP-A No. 2009-158952. At this time, the easy adhesion layer of the back sheet was attached to contact the transparent filler that embeded solar cell devices.

Table 1 shows the manufacturing conditions of the PET films and Table 2 shows the characteristics of the films.

TABLE 1

| | | | | Extrusion process | | | | | |
|---|---|---|---|---|---|---|---|---|---|
| | Pellet raw material | | | | Melt | | Longitudinal stretching process | | |
| | AV | | | Melt | Cooling | Thickness | Longitudinal | Longitudinal | |
| | (terminal | | | ejection | rate | of | stretching | stretching | Longitudinal |
| | COOH) | | | temp | (° C./ | unstretched | temp | stress | stretch ratio |
| | (eq/ton) | IV | Resin used | (° C.) | min) | film (mm) | (° C.) | (Mpa) | (times) |
| Ex 1 | 15 | 0.78 | Solid-phase | 285 | 500 | 3.5 | 91 | 12 | 3.5 |
| | | | polymerized | | | | | | |
| | | | PET 1 | | | | | | |
| Ex 2 | ″ | ″ | ″ | ″ | 800 | ″ | ″ | ″ | ″ |
| Ex 3 | ″ | ″ | ″ | ″ | 250 | ″ | ″ | ″ | ″ |
| Comp | ″ | ″ | ″ | ″ | 200 | ″ | ″ | ″ | ″ |
| Ex 1 | | | | | | | | | |
| Comp | ″ | ″ | ″ | ″ | 850 | ″ | ″ | ″ | ″ |
| Ex 2 | | | | | | | | | |
| Ex 4 | ″ | ″ | ″ | ″ | 600 | 3.2 | ″ | 7 | 2.5 |
| Ex 5 | ″ | ″ | ″ | ″ | ″ | 3.1 | ″ | 10 | 3.3 |
| Ex 6 | ″ | ″ | ″ | ″ | ″ | 2.0 | ″ | 15 | 4.5 |
| Comp | ″ | ″ | ″ | ″ | ″ | 3.2 | ″ | 4 | 2.4 |
| Ex 3 | | | | | | | | | |
| Comp | ″ | ″ | ″ | ″ | ″ | 3.2 | ″ | 18 | 5.0 |
| Ex 4 | | | | | | | | | |
| Ex 7 | ″ | ″ | ″ | ″ | ″ | 4.0 | 98 | 5 | 3.5 |
| Ex 8 | ″ | ″ | ″ | ″ | ″ | ″ | 83 | 15 | ″ |
| Comp | ″ | ″ | ″ | ″ | ″ | ″ | 100 | 4 | ″ |
| Ex 5 | | | | | | | | | |
| Comp | ″ | ″ | ″ | ″ | ″ | ″ | 80 | 20 | ″ |
| Ex 6 | | | | | | | | | |
| Ex 9 | 12 | 0.86 | Solid-phase | 290 | 550 | 4.0 | 95 | 13 | 3.5 |
| | | | polymerized | | | | | | |
| | | | PET 2 | | | | | | |
| Ex 10 | ″ | ″ | ″ | ″ | ″ | ″ | ″ | ″ | ″ |
| Ex 11 | ″ | ″ | ″ | ″ | ″ | ″ | ″ | ″ | ″ |
| Ex 12 | ″ | ″ | ″ | ″ | ″ | ″ | ″ | ″ | ″ |
| Ex 13 | ″ | ″ | ″ | ″ | ″ | ″ | ″ | ″ | ″ |
| Ex 14 | ″ | ″ | ″ | ″ | ″ | ″ | ″ | ″ | ″ |
| Ex 15 | ″ | ″ | ″ | ″ | ″ | ″ | ″ | ″ | ″ |
| Ex 16 | ″ | ″ | ″ | ″ | ″ | ″ | ″ | ″ | ″ |
| Ex 17 | ″ | ″ | ″ | ″ | ″ | ″ | ″ | ″ | ″ |
| Ex 18 | 22 | 0.65 | Not | 275 | 300 | 1.4 | 88 | 7 | 3.6 |
| | | | solid- | | | | | | |
| | | | phase | | | | | | |
| | | | polymer- | | | | | | |
| | | | ized | | | | | | |
| | | | PET-1 | | | | | | |
| Ex 19 | 25 | 0.65 | Not | ″ | ″ | ″ | ″ | ″ | ″ |
| | | | solid- | | | | | | |
| | | | phase | | | | | | |
| | | | polymer- | | | | | | |
| | | | ized | | | | | | |
| | | | PET-2 | | | | | | |
| Comp | 27 | 0.6 | Not | ″ | ″ | ″ | ″ | 4 | ″ |
| Ex 7 | | | solid- | | | | | | |
| | | | phase | | | | | | |
| | | | polymer- | | | | | | |
| | | | ized | | | | | | |
| | | | PET-3 | | | | | | |
| Ex 20 | 23 | 0.6 | Not | 300 | 300 | 0.7 | 105 | 15 | 3.6 |
| | | | solid- | | | | | | |
| | | | phase | | | | | | |
| | | | polymer- | | | | | | |
| | | | ized | | | | | | |
| | | | PEN | | | | | | |
| | | | | Transverse stretching process | | | | Heat setting | |
| | | | | | Trans- | Trans- | Relaxation | process | |
| | | | | Trans- | verse | verse | after | Heat | |
| | | | | verse | stretching | stretch | stretching | setting | Tensile |
| | | | | stretching | stress | ratio | Relaxation | temp | force |
| | | | | temp (° C.) | (Mpa) | (times) | rate (%) | (° C.) | (kg/m) |
| | | | Ex 1 | 140 | 15.0 | 3.6 | 3.5 | 220 | 7.0 |
| | | | Ex 2 | ″ | ″ | ″ | ″ | ″ | ″ |
| | | | Ex 3 | ″ | ″ | ″ | ″ | ″ | ″ |
| | | | Comp | ″ | ″ | ″ | ″ | ″ | ″ |
| | | | Ex 1 | | | | | | |
| | | | Comp | ″ | ″ | ″ | ″ | ″ | ″ |
| | | | Ex 2 | | | | | | |
| | | | Ex 4 | ″ | 13.0 | ″ | ″ | ″ | ″ |
| | | | Ex 5 | ″ | 14.0 | ″ | ″ | ″ | ″ |
| | | | Ex 6 | ″ | 20.0 | ″ | ″ | ″ | ″ |
| | | | Comp | ″ | 10.0 | ″ | ″ | ″ | ″ |
| | | | Ex 3 | | | | | | |
| | | | Comp | ″ | 25.0 | ″ | ″ | ″ | ″ |
| | | | Ex 4 | | | | | | |
| | | | Ex 7 | ″ | 8.0 | 3.8 | ″ | ″ | 8.5 |
| | | | Ex 8 | ″ | ″ | ″ | ″ | ″ | ″ |
| | | | Comp | ″ | ″ | ″ | ″ | ″ | ″ |
| | | | Ex 5 | | | | | | |
| | | | Comp | ″ | ″ | ″ | ″ | ″ | ″ |
| | | | Ex 6 | | | | | | |
| | | | Ex 9 | 145 | 10.0 | 3.6 | 5.0 | 225 | 9.0 |
| | | | Ex 10 | ″ | 15.0 | 4.0 | ″ | ″ | ″ |
| | | | Ex 11 | ″ | 19.0 | 4.5 | ″ | ″ | ″ |
| | | | Ex 12 | 148 | 8.0 | 3.6 | ″ | ″ | ″ |
| | | | Ex 13 | 155 | 7.0 | 3.6 | ″ | ″ | ″ |
| | | | Ex 14 | 145 | 10.0 | 3.6 | ″ | 240 | ″ |
| | | | Ex 15 | ″ | ″ | ″ | ″ | 205 | ″ |
| | | | Ex 16 | ″ | ″ | ″ | ″ | 230 | 0.5 |
| | | | Ex 17 | ″ | ″ | ″ | ″ | ″ | 10.0 |
| | | | Ex 18 | 135 | 9.5 | 3.8 | 2.5 | 210 | 5.0 |
| | | | Ex 19 | ″ | ″ | ″ | ″ | ″ | ″ |
| | | | Comp | ″ | ″ | ″ | ″ | ″ | ″ |
| | | | Ex 7 | | | | | | |
| | | | Ex 20 | 165 | 20.0 | 3.8 | 3.5 | 230 | 5.0 |

TABLE 2

| | Characteristics of film | | | | | | | | | |
|---|---|---|---|---|---|---|---|---|---|---|
| | | | | | | | Difference | Increase in AV | | |
| | | | | | | Equilibrium | between | before and after | | |
| | | Thickness | AV | | Degree of | moisture | moisture | 80-hour thermal | | |
| | Thickness | variation | (equivalents/ | | crystallinity | content | contents | treatment | Hydrolysis | Dimension |
| | (μm) | (%) | ton) | IV | (%) | (wt %) | (wt %) | (equivalents/ton) | resistance | stability |
| Example 1 | 280 | ±0.5 | 17 | 0.75 | 34 | 0.18 | 0.02 | 45 | A | A |
| Example 2 | 280 | ±1 | 17 | 0.75 | 30 | 0.25 | 0.05 | 50 | A | B |
| Example 3 | 280 | ±2 | 18 | 0.74 | 40 | 0.10 | 0.06 | 60 | B | A |
| Comparative | 280 | ±5 | 18 | 0.74 | 42 | 0.05 | 0.07 | 70 | D | C |
| Example 1 | | | | | | | | | | |
| Comparative | 280 | ±6 | 17 | 0.75 | 28 | 0.28 | 0.09 | 75 | D | D |
| Example 2 | | | | | | | | | | |
| Example 4 | 350 | ±3 | 17 | 0.75 | 31 | 0.25 | 0.05 | 65 | B | A |
| Example 5 | 260 | ±0.4 | 17 | 0.75 | 34 | 0.20 | 0.03 | 48 | A | A |
| Example 6 | 125 | ±0.2 | 17 | 0.75 | 38 | 0.13 | 0.02 | 40 | A | B |
| Comparative | 360 | 6 | 17 | 0.75 | 27 | 0.29 | 0.06 | 73 | D | C |
| Example 3 | | | | | | | | | | |
| Comparative | Ruptured when transverse stretching was performed after longitudinal stretching | | | | | | | | | |
| Example 4 | | | | | | | | | | |
| Example 7 | 300 | ±3 | 17 | 0.75 | 30 | 0.24 | 0.05 | 65 | B | A |
| Example 8 | 300 | ±0.9 | 17 | 0.75 | 37 | 0.17 | 0.02 | 36 | A | B |
| Comparative | 300 | ±5 | 17 | 0.75 | 26 | 0.27 | 0.12 | 80 | D | C |
| Example 5 | | | | | | | | | | |
| Comparative | 300 | ±2 | 17 | 0.75 | 36 | 0.19 | 0.10 | 32 | B | D |
| Example 6 | | | | | | | | | | |
| Example 9 | 320 | ±0.8 | 14 | 0.83 | 36 | 0.16 | 0.02 | 38 | A | A |
| Example 10 | 275 | ±0.6 | 14 | 0.83 | 38 | 0.13 | 0.01 | 33 | A | A |
| Example 11 | 253 | ±0.2 | 14 | 0.83 | 39 | 0.13 | 0.01 | 30 | A | B |
| Example 12 | 320 | ±0.9 | 14 | 0.84 | 35 | 0.24 | 0.04 | 55 | B | B |
| Example 13 | 320 | ±1.5 | 14 | 0.84 | 34 | 0.25 | 0.05 | 66 | C | B |
| Example 14 | 320 | ±1 | 14 | 0.83 | 39 | 0.24 | 0.03 | 65 | C | B |
| Example 15 | 320 | ±1 | 14 | 0.83 | 34 | 0.25 | 0.05 | 36 | A | C |
| Example 16 | 320 | ±2 | 14 | 0.83 | 36 | 0.17 | 0.04 | 52 | B | A |
| Example 17 | 320 | ±1 | 14 | 0.83 | 36 | 0.17 | 0.05 | 57 | B | C |
| Example 18 | 100 | ±0.5 | 23 | 0.65 | 36 | 0.23 | 0.05 | 62 | B | B |
| Example 19 | 100 | ±0.8 | 25 | 0.64 | 36 | 0.23 | 0.06 | 65 | C | B |
| Comparative | 100 | ±2 | 28 | 0.58 | 35 | 0.25 | 0.10 | 90 | D | D |
| Example 7 | | | | | | | | | | |
| Example 20 | 50 | ±0.5 | 23 | 0.60 | 34 | 0.18 | 0.02 | 32 | A | A |

As shown in Tables 1 and 2, it can be found that, compared to the Comparative Examples, the Examples have no D evaluation in any of hydrolysis resistance and dimension stability and thus have an excellent weather resistance.

All publications, patent applications, and technical standards mentioned in this specification are herein incorporated by reference to the same extent as if each individual publication, patent application, or technical standard was specifically and individually indicated to be incorporated by reference.

What is claimed is:

1. A biaxially oriented polyester film having:
an equilibrium moisture content of from 0.1% by mass to 0.25% by mass;
a difference between moisture contents measured at 10 cm intervals of from 0.01% by mass to 0.06% by mass;
a degree of crystallinity of from 30% to 40%;
a concentration of terminal carboxyl groups of from 5 equivalents/ton to 25 equivalents/ton; and
a thickness of from 100 μm to 350 μm.

2. The polyester film according to claim 1, having a thickness of from 255 μm to 350 μm.

3. The polyester film according to claim 1, having an intrinsic viscosity of from 0.6 to 1.3.

4. The polyester film according to claim 1, wherein an increase in the concentration of terminal carboxyl groups after performing an 80-hour long thermal treatment under an environment of 120° C. and 100% RH is from 30 equivalents/ton to 65 equivalents/ton.

5. A manufacturing method of a polyester film, comprising:
cooling a molten film-shaped polyester extruded from an extrusion die at a rate of from 250° C./min to 800° C./min; and
performing a longitudinal stretching in a length direction with a stretching stress of from 5 MPa to 15 MPa and a stretch ratio of from 2.5 times to 4.5 times, and a transverse stretching in a width direction, on the cooled film-shaped polyester, so that a thickness of the polyester film after the longitudinal stretching and the transverse stretching becomes from 100 μm to 350 μm.

6. The manufacturing method of a polyester film according to claim 5, wherein the thickness of the polyester film after the longitudinal stretching and the transverse stretching becomes from 255 μm to 350 μm.

7. The manufacturing method of a polyester film according to claim 5, wherein the molten film-shaped polyester is cooled by a cast roll.

8. The manufacturing method of a polyester film according to claim 5, wherein the transverse stretching is performed with a stretching stress of from 8 MPa to 20 MPa and a stretch ratio of from 3.4 times to 4.5 times.

9. The manufacturing method of a polyester film according to claim 5, further comprising, after the longitudinal stretching and the transverse stretching, performing a heat setting treatment on the polyester film with a tensile strength of from 1 kg/m to 10 kg/m and at a temperature of from 210° C. to 230° C.

10. The manufacturing method of a polyester film according to claim 5, wherein solid-phase polymerized pellets are used as a polyester to be extruded from the extrusion die.

11. A polyester film for sealing a back face of a solar cell, which is a polyester film manufactured by the manufacturing method according to claim 5.

12. A protective film for a back face of a solar cell, comprising the polyester film according to claim 1.

13. A solar cell module comprising the polyester film according to claim 1.
